(19) United States
(12) Patent Application Publication
(10) Pub. No.: US 2026/0360413 A1
(43) Pub. Date: Nov. 12, 2026

(54) MEMORY DEVICE FOR SATISFYING BOUNDED FAULT CONDITION

(71) Applicant: Samsung Electronics Co., Ltd., Suwon-sI (KR)

(72) Inventors: Myungkyu Lee, Suwon-si (KR); Yejun KO, Suwon-si (KR); Sunghye Cho, Suwon-si (KR); Kijun Lee, Suwon-si (KR)

(21) Appl. No.: 19/384,289

(22) Filed: Nov. 10, 2025

(30) Foreign Application Priority Data
May 7, 2025 (KR) 10-2025-0059309

(51) Int. Cl. G11C 11/4094; G11C 11/4096; G11C 29/00

(52) U.S. Cl. CPC G11C 11/4094; G11C 11/4096; G11C 29/783

(57) ABSTRACT

A memory device includes a memory cell array with first to third sub-memory cell arrays respectively corresponding to first to third address regions and each comprising a plurality of bit lines. The memory cell array includes a fourth sub-memory cell array corresponding to a fourth address region and including a plurality of redundancy bit lines replacing faulty bit lines. The memory device includes peripheral circuitry configured to receive a first data and a second data respectively corresponding to the first and second address regions through first and second input/output pins. Based on at least one of the bit lines of the first sub-memorial cell array having been replaced with the plurality of redundancy bit lines, the memory device stores the first data in the fourth sub-memory cell array and the second data in the third sub-memory cell array.

### CROSS-REFERENCE TO RELATED APPLICATIONS

This application claims priority under 35 U.S.C. § 119 to Korean Patent Application No. 10-2025-0059309 filed on May 7, 2025, in the Korean Intellectual Property Office, the disclosures of which are incorporated by reference herein in their entireties.

### BACKGROUND

Semiconductor memory is divided into volatile memory devices such as SRAM and DRAM, in which stored data disappears when power supply is cut off, flash memory devices, and nonvolatile memory devices such as PRAM, MRAM, RRAM, and FRAM, in which data stored even when power supply is cut off is maintained.

### SUMMARY

Implementations of the present disclosure provide a memory device having improved reliability, a method for operating the same, and a memory system.

According to some implementations, a memory device comprising a memory cell array comprising a first sub-memory cell array corresponding to a first address region and including a plurality of first bit lines, a second sub-memory cell array corresponding to a second address region and including a plurality of second bit lines, a third sub-memory cell array corresponding to a third address region and including a plurality of third bit lines, and a fourth sub-memory cell array corresponding to a fourth address region and including a plurality of redundancy bit lines configured to replace faulty bit lines among the plurality of first to third bit lines, and a peripheral circuit configured to receive first data and second data corresponding to the first address region and the second address region, respectively, through a first input/output pin and a second input/output pin from an external device, when at least some of the plurality of first bit lines are replaced with the plurality of redundancy bit lines, store, the first data in the fourth sub-memory cell array and the second data in the third sub-memory cell array.

According to some implementations, a method of operating a memory device comprising a memory cell array comprising first to third sub-memory cell arrays respectively corresponding to a first to third address region and each comprising a plurality of bit lines and a fourth sub-memory cell array corresponding to a fourth address region and comprising a plurality of redundancy bit lines to replace faulty bit lines, the method comprising, receiving, first and second data corresponding to the first and second address regions respectively through first and second input/output pins, determining, whether there is at least some of bit lines of the plurality of bit lines replaced with the plurality of redundancy bit line, and when at least some of the bit lines of the first sub-memory cell array replaced with the plurality of redundancy bit lines, storing, the first data in the fourth sub-memory cell array and storing the second data in the third sub-memory cell array.

According to some implementations, a memory system comprising a memory device and a memory controller configured to control the memory device, wherein the memory device comprising, a memory cell array comprising first to fifth sub-memory cell arrays respectively corresponding to a first to fifth address region and each comprising a plurality of bit lines and a sixth sub-memory cell array corresponding to a sixth address region and comprising a plurality of redundancy bit lines to replace faulty bit lines, an input/output circuit including first to fourth input/output pins, and configured to respectively receive, from the memory controller, first to fourth data respectively corresponding to the first to fourth address regions through the first to fourth input and output pins, an ECC circuit configured to perform error correction code (ECC) encoding on the first to fourth data to generate write data including the first to fourth data and parity data, an input/output gating circuit configured to transfer the write data to the memory cell array and control logic circuit configured to generate a gating control signal associated with the storage location of the first to fourth data, wherein the input/output gating circuit further configured to when at least some of the plurality of bit lines of the first sub-memory cell array replaced with the plurality of redundancy bit lines, transfer, based on the gating control signal, the first data to the sixth sub-memory cell array, the second data to the fifth sub-memory cell array, the third data to the third sub-memory cell array, and the fourth data to the fourth sub-memorial cell array.

### BRIEF DESCRIPTION OF THE DRAWINGS

The above and other objects and features of the present disclosure will become apparent by describing in detail implementations thereof with reference to the accompanying drawings.

FIG. 1 is a block diagram illustrating a memory device according to some implementations of the present disclosure.

FIGS. 2A and 2B are diagrams for illustrating the memory cell array of FIG. 1.

FIGS. 3A, 3B and 3C are diagrams for illustrating operation of the memory device of FIG. 1.

FIGS. 4A, 4B, 4C and 4D are diagrams for illustrating an example of operation of the memory device of FIG. 1 in the event of a failure of a sub-word line driver.

FIGS. 5A, 5B and 5C are diagrams for illustrating an operation of a memory device according to some implementations of the present disclosure.

FIGS. 6A, 6B and 6C are diagrams for describing an operation of the memory device according to some implementations of the present disclosure.

FIGS. 7A and 7B are block diagrams for illustrating the input/output gating circuit of FIG. 3A.

FIGS. 8A and 8B are diagrams for illustrating the operation of the switching circuit of FIGS. 7A and 7B.

FIG. 9 is a flowchart for illustrating a write operation of the memory device of FIG. 1.

FIG. 10 is a flowchart for illustrating a read operation of the memory device of FIG. 1.

FIG. 11 is a diagram for illustrating a memory system according to some implementations of the present disclosure.

FIG. 12 is a diagram illustrating a system 1000 according to some implementations of the present disclosure.

### DETAILED DESCRIPTION

In the following, implementations of the present disclosure will be described clearly and in detail to the extent that a person skilled in the art may easily practice the present disclosure.

Terms such as “block,” “unit or portion,” “logic,” and the like used in the detailed description, or functional blocks shown in the drawings to correspond thereto, may be implemented in the form of software, hardware, or a combination thereof.

In the following, where various components are listed via the conjunction of “or,” this may refer to each of the listed components, or to a combination of at least some. For example, “A, B, or C” may mean each of A, B, and C, or a combination of A and B, a combination of B and C, a combination of A, and C, and/or a combination of A, B and C.

DRAM is widely used as a system memory of a mobile device or a computer device. The DRAM device outputs data to an external device via input/output pins. In order to facilitate error correction in an external device (e.g., a memory controller), the DRAM device may satisfy a bounded fault condition in which the number of input/output pins that output error data among the input/output pins is limited to within a specific number.

DRAM devices may include redundancy bit lines to replace faulty bit lines. After the faulty bit lines are replaced with redundancy bit lines, a fault may occur in the circuitry that controls the memory cells of the DRAM. In this case, there may be a problem that the DRAM device does not satisfy the bounded fault condition.

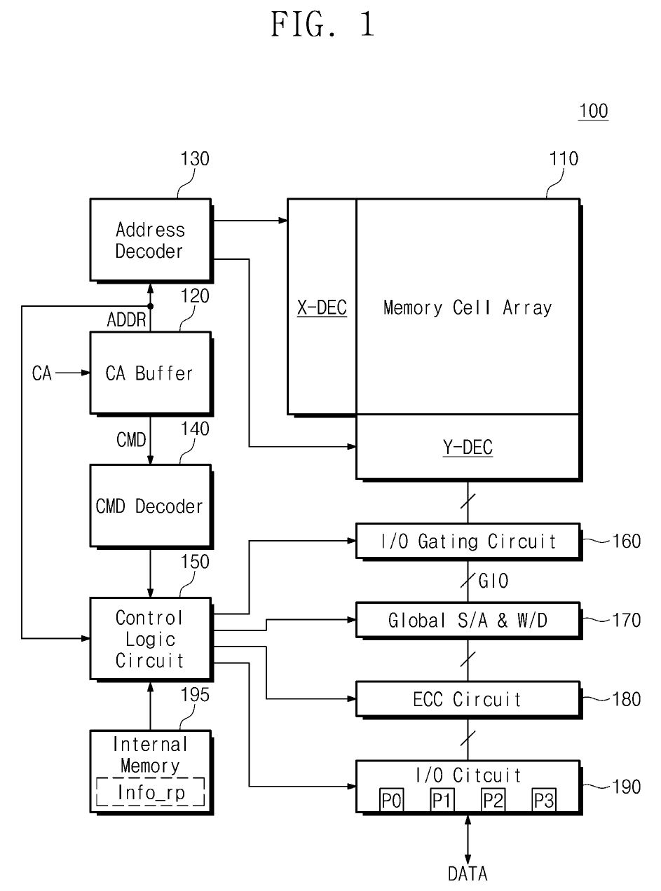

FIG. 1 is a block diagram illustrating a memory device according to some implementations of the present disclosure. Referring to FIG. 1, a memory device 100 may include a memory cell array 110, a command and address CA buffer 120, an address decoder 130, a command decoder 140, a control logic circuit 150, an input/output gating circuit 160, a global sense amplifier and write driver 170, an error correction code (ECC) circuit 180, an input/ output circuit 190, and an internal memory 195. In some implementations, the memory device 100 may be a dynamic random access memory (DRAM) device, but the scope of the present disclosure is not limited thereto.

The memory cell array 110 may include a plurality of memory cells. The plurality of memory cells may be aligned along a row direction and a column direction and may be connected with word lines and bit lines. In some implementations, each of the plurality of memory cells may be a DRAM cell including an access transistor and a storage capacitor. In some implementations, the plurality of word lines may be driven by an X-decoder (or row decoder) X-DEC, and the plurality of bit lines may be drove by a Y-decoders (or column decoders) Y-DEC.

In some implementations, memory cell array 110 may include redundancy bit lines. The redundancy bit lines may replace faulty bit lines. For example, memory cells connected to the redundancy bit lines may store data corresponding to an address of faulty bit lines. Accordingly, the redundancy bit lines may replace the faulty bit lines. The memory cell array 110 may include a plurality of sub-memory cell arrays including the bit lines and an auxiliary sub-memory cell array including the redundancy bit lines.

The CA buffer 120 may be configured to receive a command/address (CA) from an external device (e.g., a memory controller) and buffer the received signals.

The address decoder 130 may receive the address ADDR from the CA buffer 120 and decode the received address ADDR. The address decoder 130 may control the word lines of the memory cell array 110 based on a decoding result. For example, the word lines of the memory cell array 110 may be coupled with a row decoder X-DEC. The address decoder 130 may control the word lines of the memory cell array 110 by controlling the row decoder X-DEC. For example, the address decoder 130 may generate a column selection signal based on a decoding result, and the column decoder Y-DEC may control or select a plurality of bit lines connected to the memory cell array 110 based on the column selection signal.

The command decoder 140 may decode the command CMD stored in the CA buffer 120. Control logic circuit 150 may control the components of memory device 100 based on the decoded results of command decoder 140. For example, when the command signal stored in the CA buffer 120 is a write command, the control logic circuit 150 may control the operations of the global sense amplifier and the write driver 170, and the input/output gating circuit 160 (that is, activate the write driver) such that the input/output data DATA received through the input/output circuit 190 is written to the memory cell array 110 in response to a decoding result of the command decoder 140. Alternatively, when the command signal stored in the CA buffer 120 is a read command, the control logic circuit 150 may control the operation of the input/output gating circuit 160 and the global sense amplifier and the write driver 170 (that is, activate the sense amplifier) such that data stored in the memory cell array 110 is read out in response to a decoding result of the command decoder 140.

In the read operation, the input/output gating circuit 160 may select a plurality of data to be output to the outside from among the plurality of read data from the selected bit lines. In addition, during a write operation, the input/output gating circuit 160 may transfer data input through the global input/output lines GIO to bit lines in which data is to be stored among the selected bit lines.

For example, 1st bit lines of the selected bit lines may be replaced with 1st redundancy bit lines. In this case, the input/output gating circuit 160 may transmit data read from the 1st redundancy bit lines to the global input/output lines GIO in a read operation and may transmit data corresponding to the 1st bit lines input from the global input/output lines GIO to the 1st redundancy bit lines in a write operation.

In some implementations, the input/output gating circuit 160 may operate under the control of the control logic circuit 150. In some implementations, the control logic circuit 150 may receive the repair information info_rp from the internal memory 195 and may receive the address ADDR from the CA buffer 120. The repair information info_rp may include information about a position of faulty bit lines replaced with the redundancy bit lines. The control logic circuit 150 may control the input/output gating circuit 160 based on the address ADDR and the repair information info_rp.

The global sense amplifier and write driver 170 may store data in memory cell array 110 or read data stored in the memory cell array 110, under the control of the control logic circuit 150. In some implementations, the global sense amplifier and write driver 170 may be coupled to the memory cell array 110 through global input/output lines GIOs.

The ECC circuit 180 may be configured to correct errors in data to be stored in the memory cell array 110. For example, the ECC circuit 180 may perform ECC encoding on the 1st data to be stored in the memory cell array 110 to generate parity data. The generated parity data may be stored in the memory cell array 110 along with the 1st data. The ECC circuit 180 may then be configured to perform ECC decoding based on the parity data and the 1st data read from the memory cell array 110 to correct errors in the read 1st data. In some implementations, the ECC circuit 180 may not be able to correct more than 1-bit errors in the input data.

The input/output circuit 190 may exchange input/output data DATA with an external device (e.g., a memory controller). The input/output circuit 190 may include 0th to 3rd input/output pins P0 to P3 that transmit and receive the input/output data DATA. The input/output circuit 190 may transmit the input/output data DATA through the 0th to 3rd input/output pins P0 to P3 during a burst length. Although FIG. 1 illustrates that the input/output circuit 190 includes four input/output pins P0 to P3, the present disclosure is not limited thereto, and the number of the input/output pin may be variously changed.

In some implementations, the memory device 100 may operate in a first mode or a second mode. In the first mode, the 0th to 3rd input/output pins P0 to P3 may operate as the 0th to 3rd DQ pins. In the second mode, the 0th to 3rd input/output pins P0 to P3 may operate as the 0th to 3rd DQB pins. For example, in the read operation in the first mode, the input/output circuit 190 may output data read from the sub-memory cell arrays corresponding to the 0th to 3rd DQ pins in the data received from the ECC circuit 180 through the 0th to 3rd input/output pins P0 to P3. For example, in the read operation in the second mode, the input/output circuit 190 may output data output from the sub-memory cell arrays corresponding to the 0th to 3rd DQB pins in the data received from the ECC circuit 180 through the 0th to 3rd input/output pins P0 to P3.

In some implementations, an operation mode of the memory device 100 may be determined based on the command/address CA. Specifically, the operation mode may be determined by a bit value of a specific bit among bits of the command/address CA. In some implementations, the memory device 100 may operate in a first mode when a bit value of a specific bit (e.g., the 11th bit CA) of the command/address CA is “0” and may operate in a second mode when the bit value of the specific bit is “1”. In some implementations, the specific bit may be a most significant bit (MSB) bit of the column address. However, implementations of the present disclosure are not limited thereto.

The internal memory 195 may store repair information info_rp. The repair information info_rp may include information on a location of faulty bit lines replaced with redundancy bit lines of the memory cell array 110. In some implementations, the internal memory 195 may be a read only memory (ROM), but the present disclosure is not limited thereto.

In some implementations, the remaining components (e.g., CA buffer 120, address decoder 130, command decoder 140, control logic circuitry 150, input/output gating circuitry 160, global sense amplifier and write driver 170, ECC circuitry 180, input/output circuitry 190, and internal memory 195) other than memory cell array 110 may be peripheral circuits, which may perform various operations (e.g., read operations or write operations, etc.) on memory cell array 110 based on commands and addresses received from external devices (e.g., memory controllers).

As described above, the memory device 100 may output the input/output data DATA to an external device (e.g., a memory controller) through the input/output pins P0 to P3 of the input/output circuit 190. An external device (e.g., a memory controller) may receive input/output data DATA and correct an error in the input/output data DATA. To enable error correction of an external device (e.g., a memory controller), the memory device 100 may need to output input/output data DATA while satisfying a bounded fault condition.

The bounded fault condition may refer to a condition that limits error bits generated in the input/output data DATA during a single burst length to be output only through a specific number of the following input/output pins. In some implementations, when the number of input/output pins of the memory device 100 is four, the specific number may be two.

For example, the memory cell array 110 may include 0th to 3rd sub-memory cell arrays, and an auxiliary sub-memory cell array. Each of the 0th through 3rd sub-memory cell arrays may include memory cells coupled with a plurality of bit lines. The auxiliary sub-memory cell array may include memory cells coupled with redundancy bit lines. The auxiliary sub-memory cell array may include memory cells coupled with bit lines and storing parity data for ECC decoding.

For example, when there are no bit lines replaced with a redundancy bit line, the memory device 100 may be configured to output the 0th data read from the 0th sub-memory cell array through the 0th input/output pin P0, output the 1st data read from the 1st sub-memory cell array through the 1st input/output pin P1, output the 2nd data read from the 2nd sub-memory cell array through the 2nd input/output pin, and output the 3rd data read from the 3rd sub-memory cell array through the 3rd input/output pin.

For example, if there are at least some bit lines replaced with a redundancy bit lines, the memory device 100 may be configured to output data read from memory cells coupled with the redundancy bit lines via an input/output pin corresponding to a sub-memory cell array including the bit lines replaced with the redundancy bit lines. As a more detailed example, when bit lines of the 0th sub-memory cell array are replaced with redundancy bit lines, the memory device 100 may be configured to output 4th data read from memory cells connected with the redundancy bit line through the 0th input/output pin P0, and output 1st to 3rd data through the 1st to 3rd input/output pins P1 to P3, respectively.

For example, after the bit lines of the 0th sub-memory cell array are replaced with redundancy bit lines, a fault may occur in the sub-word line driver that drives the word lines of the 3rd sub-memory cell array and the auxiliary sub-memory cell array. In this case, each of the 3rd data, the 4th data, and the parity data may include error bits. As an error occurs in the parity data, the ECC circuit 180 may perform mis-correction on at least one of the 1st to 4th data. Specifically, the ECC circuit 180 may determine a specific data bit of the data bits of the 1st data or the 2nd data in which no error exists as an error bit to perform mis-correction. Therefore, the 1st data or the 2nd data on which the ECC decoding is performed may include an error bit.

For example, when an error due to mis-correction occurs in the 1st data, then the 4th data, the 1st data, and the 3rd data output through the 0th input/output pin P0, the 1st input/output pin P1, and the 3rd input/output pin P3 may include error bits. That is, the memory device 100 may output error bits through three input/output pins. Accordingly, the memory device 100 may not satisfy the bounded fault condition.

According to some implementations of the present disclosure, when bit lines are replaced with redundancy bit lines, the memory device 100 may control the input/output gating circuit 160 to change the storage position of the input/output data DATA. Accordingly, even when a fault occurs in the sub-word line driver of the auxiliary sub-memory cell array, the memory device 100 may output the input/output data DATA while satisfying the bounded fault condition. The configuration and operation of the memory device 100 according to some implementations of the present disclosure are described in more detail with reference to the following drawings.

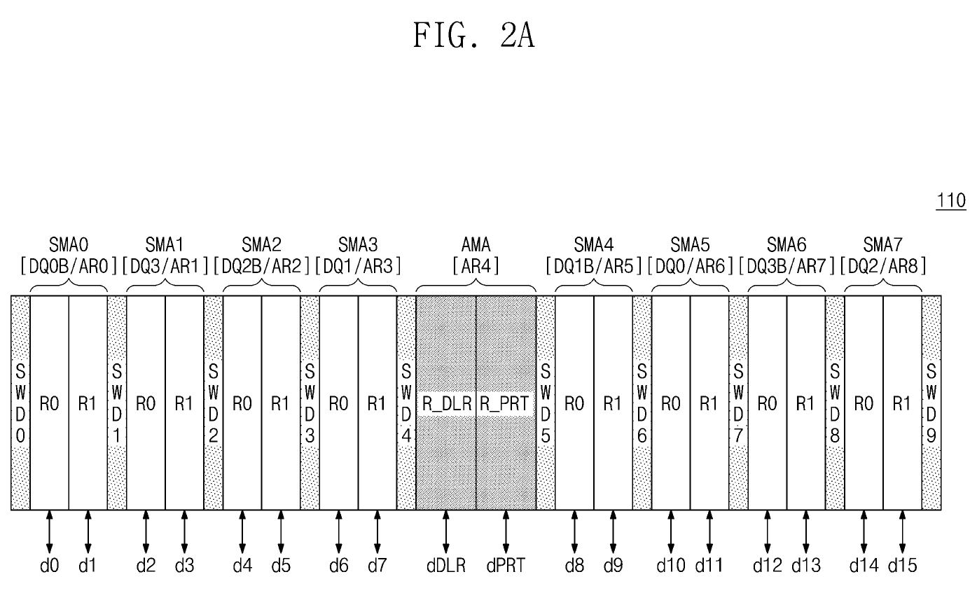

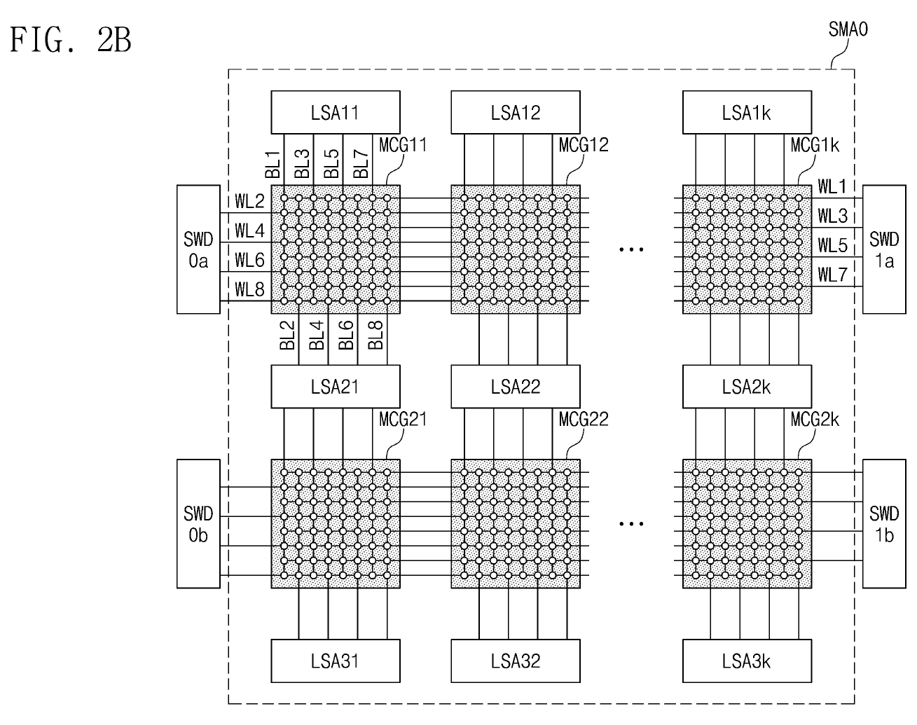

FIGS. 2A and 2B are diagrams for illustrating the memory cell array of FIG. 1. Referring to FIGS. 1 and 2A, the memory cell array 110 may include a plurality of sub-memory cell arrays SMA0 to SMA7, an auxiliary sub-memory cell array AMA, and 0th to 9th sub-word line drivers SWD0 to SWD9.

Each of the plurality of sub-memory cell arrays SMA0 to SMA7 may include a plurality of memory cells, a plurality of bit lines and word lines connected with the plurality of memory cells. In addition, each of the plurality of sub-memory cell arrays SMA0 to SMA7 may include a 0th region R0 and a 1st region R1.

The 0th region R0 of the 0th sub-memory cell array SMA0 may store the 0th data d0, and the 1st region R1 may store the 1st data d1. The 0th region R0 of the 1st sub-memory cell array SMA1 may store the 2nd data d2, and the 1st region R1 may store the 3rd data d3. The 0th region R0 of the 2nd sub-memory cell array SMA2 may store 4th data d4, and the 1st region R1 may store 5th data d5. The 0th region R0 of the 3rd sub-memory cell array SMA3 may store the 6th data d6, and the 1st region R1 may store the 7th data d7. The 0th region R0 of the 4th sub-memory cell array SMA4 may store the 8th data d8, and the 1st region R1 may store the 9th data d9. The 0th region R0 of the 5th sub-memory cell array SMA5 may store the 10th data d10, and the 1st region R1 may store the 11th data d11. The 0th region R0 of the 6th sub-memory cell array SMA6 may store the 12th data d12, and the 1st region R1 may store the 3rd data d31. The 0th region R0 of the 7th sub-memory cell array SMA7 may store the 14th data d14, and the 1st region R1 may store the 15th data d15.

The auxiliary sub-memory cell array AMA may include a data line redundancy (DLR) region R_DLR and a parity region R_PRT. The DLR region R_DLR may include a plurality of redundancy memory cells and redundancy bit lines and word lines connected to the redundancy memory cell. The DLR region R_DLR may store DLR data dDLR corresponding to an address of bit lines replaced with the redundancy bit lines. The parity region R_PRT of the auxiliary sub-memory cell array AMA may include a plurality of memory cells and bit lines and word lines connected with the memory cells. The parity region R_PRT may store parity data dPRT generated based on input/output data DATA received from an external device (e.g., a memory controller).

Each of the 0th to 9th sub-word line drivers SWD0 to SWD9 may be located on both sides of each of the plurality of sub-memory cell arrays SMA0 to SMA7 and the auxiliary sub-memory cell array SMA and may be configured to control or drive some of the word lines of an adjacent sub-memory cell array.

In some implementations, the 0th to 3rd sub-memory cell arrays SMA0 to SMA3 may respectively correspond to the 0th to 3rd address regions AR0 to AR3, the auxiliary sub-memory cell array AMA may correspond to the 4th address region AR4, and the 4th to 7th sub-memory cell arrays SMA4 to SMA7 may respectively correspond to 5th to 8th address regions AR5 to AR8. At this time, in the write operation in the first operation mode, the 0th input/output pin P0 operating as the 0th DQ pin DQ0 may receive data corresponding to the 6th address region AR6, the 1st input/output pin P1 operating as the 1st DQ pin DQ1 may receive the data corresponding to the 3rd address region AR3, the 2nd input/output pin P2 operating as the 2nd DQ pin DQ2 may receive the data corresponds to the 8th address region AR8, and the 3rd input/output pin P3 operating as the 3rd DQ pin DQ3 may receive the data correspond to the 1st address region AR1.

In addition, in the write operation in the second operation mode, the 0th input/output pin P0 operating as the 0th DQB pin DQ0B may receive data corresponding to the 0th address region AR0, the 1st input/output pin P1 operating as the first DQB pin DQ1B may receive data corresponding to the 5th address region AR5, the 2nd input/output pin P2 operating as the 2nd DQB pin DQ2B may receive data corresponding to the 2nd address region AR2, and the 3rd input/output pins P3 operating as the 3rd DQB pins DQ3B may receive the data corresponding to the 7th address region AR7.

Accordingly, the 0th sub-memory cell array SMA0 may correspond to the 0th DQB pin DQ0B, the 1st sub-memory cell array SMA1 may correspond to the 3rd DQ pin DQ3, the 2nd sub-memory cell array SMA2 may correspond to the 2nd DQB pin DQ2B, the 3rd sub-memory cell array SMA3 may correspond to the 1st DQ pin DQ1, the 4th sub-memory cell array SMA4 may correspond to the 1st DQB DQ1B pin, the 5th sub-memory cell array SMA5 may correspond to the 0th DQ pin DQ0, the 6th sub-memory cell array SMA6 may correspond to the 3rd DQB pin DQ3B, and the 7th sub-memory cell array SMA7 may correspond to the 2nd DQ pin DQ2.

For example, in some other implementations, the 2nd sub-memory cell array SMA2 may correspond to the 1st DQ pin DQ1. In addition, a fault may occur in the 2nd sub-word line drivers SWD2. In this case, in the first operation mode, an error may occur in a plurality of data d2 to d5 output through the 1st DQ pin DQ1 and the 2nd DQ pin DQ2. According to some implementations of the present disclosure, sub-memory cell arrays SMA1, SMA3, SMA5, and SMA7 corresponding to DQ pins DQ0 to DQ3 and sub-memory cell arrays SMA0, SMA2, SMA4, and SMA6 corresponding to DQB pins DQ0B to DQ3B may be alternately disposed with each other. Accordingly, for example, even if a failure occurs in the 2nd sub-word line driver SWD2, it is possible to prevent an error from occurring simultaneously in the data d6, d7, d2, and d3 output through the 1st DQ pin DQ1 and the 2nd DQ pin DQ2 in the same operation mode (e. g., first operation mode).

In some implementations, the memory device 100 may receive the input/output data DATA from an external device (e.g., a memory controller) through the 0th to 3rd input/output pins P0 to P3 during a burst length. The input/output data DATA may include 0th to 3rd sub-data. In some implementations, the burst length may be 16. Accordingly, the 0th to 3rd input/output pins P0 to P3 may receive the 1st to 3rd sub-data in units of 1 bit for each burst position (e.g., the 0th to 15th burst positions). The 0th to 3rd input/output pins P0 to P3 may respectively receive the upper 8 bits of the 0th through 3rd sub-data at the 0th to 7th burst positions and may respectively receive the lower 8 bits of 0th to 3rd sub-data in the 8th to 15th burst positions.

In this case, the 0th sub-data may be 16-bit data received through the 0th input/output pin P0, the 1st sub-data may be 16-bit data received through the 1st input/output pin P1, the 2nd sub-data may be 16-bit data received through the 2nd input/output pins P2, and the 3rd sub-data may be 16-bit data received through a 3rd input/output pin.

For example, all bit lines of the sub-memory cell arrays SMA0 to SMA7 may be normal bit lines, not faulty bit lines. Accordingly, the bit lines may not be replaced with redundancy bit lines of the auxiliary sub-memory cell array AMA. In addition, the memory device 100 may receive input/output data DATA from an external device (e.g., a memory controller) in the first mode. Accordingly, the 0th to 3rd input/output pins P0 to P3 may operate as the 0th to 3rd DQ pins DQ0 to DQ3.

In this case, the upper 8-bits of the 0th sub-data received through the 0th input/output pin P0 operating as the 0th DQ pin DQ0 may be stored as the 10th data d10 in the 0th region R0 of the 5th sub-memory cell array SMA5, and the lower 8-bits may be stored as 11th data d11 in the 1st region R1 of the 5th sub-memory cell array SMA5.

For example, the upper 8-bits of the 1st sub-data received through the 1st input/output pin P1 operating as the 1st DQ pin DQ1 may be stored as the 6th data d6 in the 0th region R0 of the 3rd sub-memory cell array SMA3, and the lower 8-bits may be stored as a 7th data d7 in the 1st region R1 of the 3rd sub-memory cell array SMA3.

The upper 8-bits of the 2nd sub-data received through the 2nd input/output pin P2 operating as the 2nd DQ pin DQ2 may be stored as the 14th data d14 in the 0th region R0 of the 7th sub-memory cell array SMA7, and the lower 8-bits may be stored as 15th data d15 in the 1st region R1 of the 7th Sub-memory Cell Array SMA7.

The upper 8-bits of the 3rd sub-data received through the 3rd input/output pin P3 operating as the 3rd DQ pin DQ3 may be stored as the 2nd data d2 in the 0th region R0 of the 1st sub-memory cell array SMA1, and the lower 8-bits may be stored as 3rd data d3 in the 1st region R1 of the 2nd sub-memory cell array SMA2. In addition, the parity data dPRT generated based on the input/output data DATA may be stored in the parity region R_PRT of the auxiliary sub-memory cell array AMA.

For example, all bit lines of the sub-memory cell arrays SMA0 to SMA7 may all be normal bit lines, not faulty bit lines. In addition, the memory device 100 may receive input/output data DATA in a read operation in the second mode. Accordingly, the 0th to 3rd input/output pins P0 to P3 may operate as the 0th to 3rd DQB pins DQ0B to DQ3B.

In this case, the upper 8-bits of the 0th sub-data received through the 0th input/output pin P0 operating as the 0th DQB pin DQ0B may be stored as the 0th data d0 in the 0th region R0 of the 1st sub-memory cell array SMA1, and the lower 8-bits may be stored as 1st data d1 in the 1st region R1 of the 1st sub-memory cell array SMA1.

The upper 8-bits of the 1st sub-data received through the 1st input/output pin P1 operating as the 1st DQB pin DQ1B may be stored as the 8th data d8 in the 0th region R0 of the 4th sub-memory cell array SMA4, and the lower 8-bits may be stored as 9-th data d9 in the 1st region R1 of the 4th sub-memory cell array SMA4.

The upper 8-bits of the 2nd sub-data received through the 2nd input/output pin P2 operating as the 2nd DQB pin DQ2B may be stored as the 4th data d4 in the 0th region R0 of the 2nd sub memory cell array SMA2, and the lower 8-bits may be stored as 5th data d5 in the 1st region R1 of the 2nd sub storage cell array SMA2.

The upper 8-bits of the 3rd sub-data received through the 3rd input/output pin P3 operating as the 3rd DQB pin DQ3B may be stored as the 12th data d12 in the 0th region R0 of the 6th sub-memory cell array SMA6, and the lower 8 bits may be stored as 13th data d13 in the 1st region R1 of the 6th sub-memory cell array SMA6). In addition, the parity data dPRT generated based on the input/output data DATA may be stored in the parity region R_PRT of the auxiliary sub-memory cell array AMA.

For example, some of the bit lines of the 0th region R0 of the 1st sub-memory cell array SMA1 may be faulty bit lines. At this time, the memory device 100 may receive the input/output data DATA in the first mode. Accordingly, the 0th to 3rd input/output pins P0 to P3 may operate as the 0th to 3rd DQ pins DQ0 to DQ3. For example, the upper 8-bits of the 3rd sub-data received through the 3rd input/output pin P3 may correspond to addresses of faulty bit lines of the 0th region R0 of the 1st sub-memory cell array SMA1.

In this case, the upper 8-bits of the 3rd sub-data received through the 3rd input/output pin P3 operating as the 3rd DQ pin DQ3 may be stored as DLR data dDLR in the 0th region R0 of the auxiliary sub-memory cell array AMA, and the lower 8-bits may be stored as the 3rd data d3 in the 1st region R1 of the 1st sub-memory cell array SMA1. That is, data corresponding to the address of the faulty bit lines may be stored in the DLR region R_DLR. Accordingly, faulty bit lines may be replaced with redundancy bit lines.

The memory device 100 may receive a read command for data stored in the memory cell array 110 from an external device (e.g., a memory controller). In this case, the 0th to 15th data d0 to d15, the DLR data dDLR, and the parity data dPRT may be read from the sub-memory cell arrays SMA0 to SMA7 and the auxiliary sub-memory cell array AMA.

Referring to FIG. 2B, the 0th sub-memory cell array SMA0 may include a plurality of memory cell groups MCG11 to MCG23 and a plurality of local sense amplifiers LSA11 to LSA3k. In FIG. 2B, some configurations of the 0th sub-memory cell array SMA0 are shown, but the scope of the present disclosure is not limited thereto. The sub-memory cell arrays SMA1 to SMA7 and the auxiliary sub-memory cell array AMA may be implemented in the same structure as the 0th sub-memory cell array SMA0 of FIG. 2B.

Each of the plurality of memory cell groups MCG11 to MCG23 may include a plurality of memory cells. Each of the plurality of memory cells may be coupled with word lines and bit lines. For example, the 11th memory cell group MCG11 may include a plurality of memory cells, and the plurality of memory cells may be connected to the word lines WL1 to WL8 and the bit lines BL1 to BL8. The remaining memory cell groups MCG12 to MCG2k may also have a structure similar to that of the 11th memory cell group MCG11, and a detailed description thereof is omitted.

The word lines WL1 to WL8 may be driven by the sub-word line drivers SWD0a to SWD1a. The 0th sub-word line drivers SWD0 of FIG. 2A may include the 0th sub-word line drivers SWD0a and SWD0b, and the 1st sub-word line driver SWD1 of FIG. 2a may include the 1st sub-word line driver SWD1a and SWD1b. For example, the 0th sub-word line driver SWD0a may be located on a first side of the 11th memory cell group MCG11 and configured to drive the 2nd, 4th, 6th, and 8th word lines WL2, WL4, WL6, and WL8. For example, the 1st sub-word line driver SWD1a may be located on a second side opposite to the first side of the 11th memory cell group MCG11 and configured to drive the 1st, 3rd, 5th, and 7th word lines WL1, WL3, WL5, and WL7. In some implementations, the 1st sub-word line driver SWD1a may be further configured to drive some of the word lines (e.g., odd word lines) of the adjacent 1st sub-memory cell array SMA1. The remaining sub-word line drivers SWD0b and SWD1b may also have a structure similar to that of the 0th sub-word line driver SWD0a or the 1st sub-word line driving SWD1a, and a detailed description thereof is omitted.

Each of the plurality of local sense amplifiers LSA11 to LSA3k may be located on both sides of each of the plurality of memory cell groups MCG11 to MCG2k and may be configured to control or drive some of the bit lines of adjacent memory cell groups. For example, the 11th local sense amplifier LSA11 may be located on the third side of the 11th memory cell group MCG11 and configured to control the 1st, 3rd, 5th, and 7th bit lines BL1, BL3, BL5, and BL7. The 21st local sense amplifier LSA21 is located on a fourth side opposite to the third side of the 11th memory cell group MCG11, and may be configured to control the 2nd, 4th, 6th, and 8th bit lines BL2, BL4, BL6, and BL8. In some implementations, the 21st local sense amplifier LSA21 may be configured to control some (e.g., even-numbered bit lines) of bit lines of the adjacent 21st memory cell group MCG21. The remaining local sense amplification units LSA12 to LSA1k and LSA22 to LSA3k may have a structure similar to that of the 11th local sense amplification unit LSA11 or the 21th local sense amplification unit LSA21, and a detailed description thereof is omitted. Each of the plurality of local sense amplifiers LSA11 to LSA3k may be connected to the global sense amplifier and the write driver 170 through the input/output gating circuit 160 and the global input/output lines GIO.

In some implementations, the plurality of sub word line drivers SWD0a to SWD1b may operate under the control of the row decoder X-DEC. For example, the plurality of sub word line drivers SWD0a to SWD1b may activate a selected word line among the plurality of word lines under the control of the row decoder X-DEC.

The plurality of local sense amplifiers LSA11 to LSA3k may operate under the control of the column decoder Y-DEC. For example, the plurality of local sense amplifiers LSA11 to LSA3k may control voltages of selected bit lines or sense voltage changes of selected bit lines under the control of the column decoder Y-DEC. In some implementations, the plurality of local sense amplifiers LSA11 to LSA33 may operate in response to column selection signals, respectively.

For example, among the plurality of local sense amplifiers LSA11 to LSA33, the 11th, 21st, and 31st local sense amplifiers LSA11, LSA21, and LSA31 located in the same 1st column may operate in response to the 1st column selection signal CSL1, the 12th, 22nd, and 32nd local sense amplifiersLSA12, LSA22, and LSA32 located in the same 2nd column may operate in responses to the 2nd column selection signal CLS2, and the 1st-k, 2nd-k, and 3rd-k local sense amplifiers LSA1k, LSA2k, and LSA3k located in the same kth column may operate in reactions to the kth column selection signal CSLk.

The structure of the 0th sub-memory cell array SMA0 described with reference to FIG. 2B is a simple example for convenience of description, and the scope of the present disclosure is not limited thereto. For example, the memory cell array 110 may further include a plurality of sub-memory cell arrays, and one sub-memory cell array may further include the plurality of memory cells.

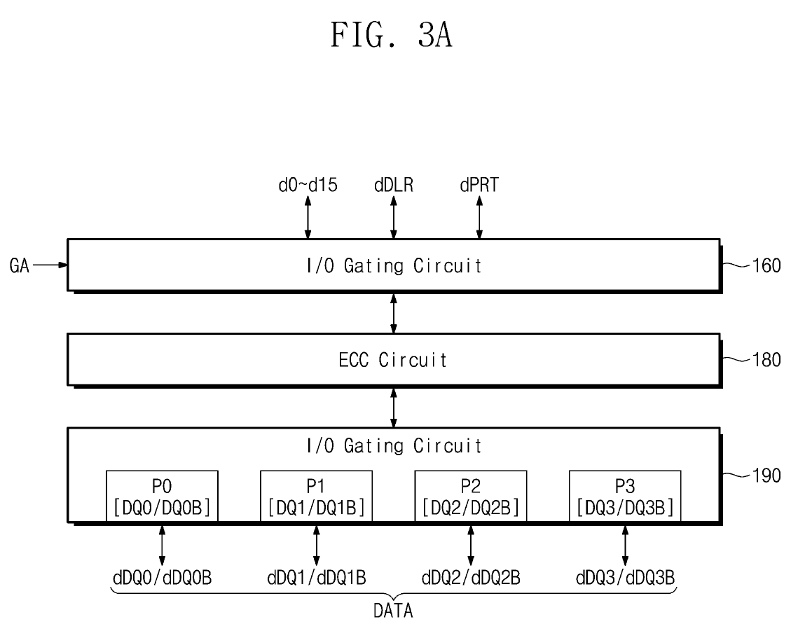

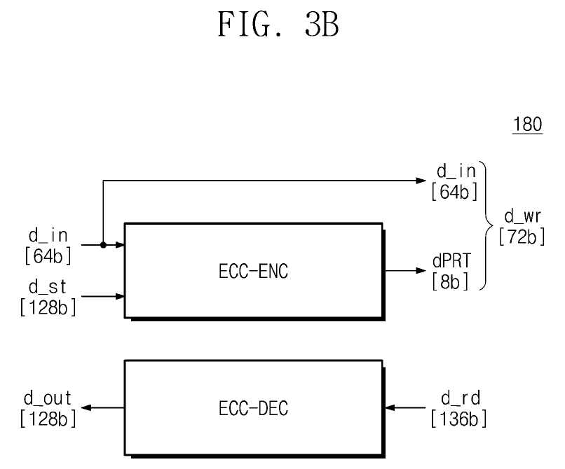

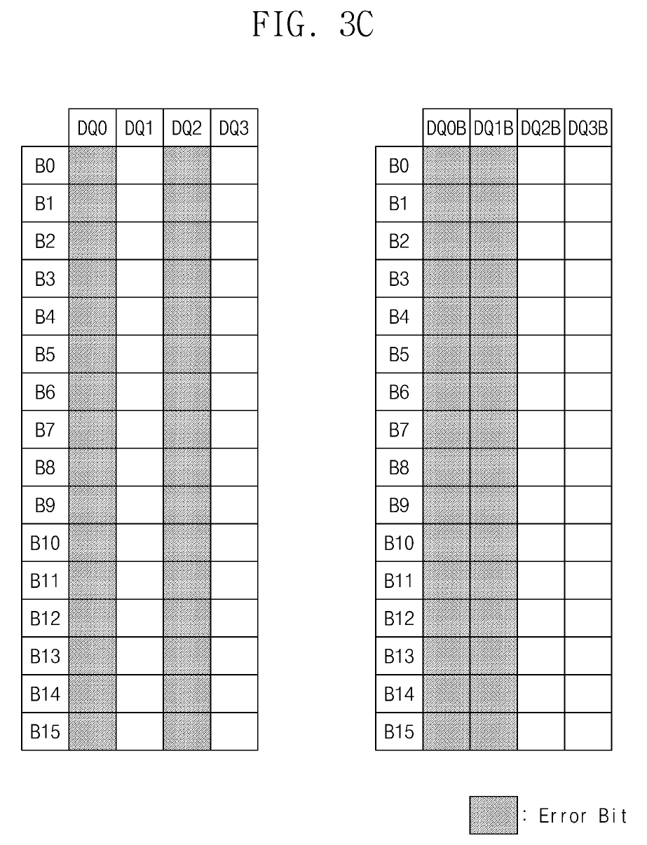

FIGS. 3A, 3B and 3C are diagrams for describing operation of the memory device of FIG. 1. For ease of description, a detailed description of unnecessary components is omitted.

Referring to FIG. 3A, in a read operation, the input/output gating circuit 160 may receive the 0th to 15th data d0 to d15, the DLR data dDLR, and the parity data dPRT from the memory cell array 110. The input/output gating circuit 160 may output the DLR data dDLR instead of data output from bit lines replaced with the redundancy bit lines among the 0th to 15th data d0 to d15 and the parity data dPRT. For example, bit lines of the 0th region R0 of the 0th sub-memory cell array SMA0 may be replaced with redundancy bit lines. In this case, the input/output gating circuit 160 may output the DLR data dDLR, the 1st to 15th data d1 to d15, and the parity data dPRT as read data. In some implementations, the input/output gating circuit 160 may output read data based on the gating control signal GA received from the control logic circuit 150.

In a write operation, the input/output gating circuit 160 may receive write data. The input/output gating circuit 160 may transmit the write data to bit lines of a storage location of the memory cell array 110 based on the gating control signal GA. For example, bit lines of the 0th region R0 of the 0th sub-memory cell array SMA0 may be replaced with redundancy bit lines. In this case, the input/output gating circuit 160 may transmit data received through the 0th DQB pin DQ0B to the DLR region R_DLR as DLR data dDLR.

In some implementations, each of the 0th to 15th data d0 to d15, the DLR data dDLR, and the parity data dPRT may be 8-bit data.

In a read operation, the ECC circuit 180 may perform ECC decoding on the read data to generate output data. In a write operation, the ECC circuit 180 may perform ECC encoding based on input data to generate write data.

Referring to FIG. 3B, the ECC circuit 180 may include an ECC encoder ECC-ENC and an ECC decoder ECC-DEC. The ECC encoder ECC-ENC may perform ECC encoding based on 64-bit input data d_in and 128-bit storage data d_st to generate 8-bit parity data dPRT. For example, in a write operation, the ECC encoder ECC-ENC may receive input data d_in received from an external device (e.g., a memory controller). In addition, the ECC encoder ECC-ENC may receive the stored data d_st read from the address of the memory cell array 110 corresponding to the input data d_in. The ECC encoder ECC-ENC may generate superimposed data by superimposing the input data d_in on the stored data d_st, and then perform ECC encoding on the superimposed data to generate parity data dPRT.

In the write operation, the memory device 100 may store the input data d_in and the parity data dPRT in the memory cell array 110. That is, the memory device 100 may operate in a read-modify-write manner. However, the present disclosure is not limited thereto, and the writing operation method of the memory device 100 may be variously changed.

The ECC decoder ECC-DEC may perform ECC decoding on the 136-bit read data d_rd to output 128-bit output data d_out. The 128-bit output data d_out may be error-corrected data.

Referring again to FIG. 3A, in the read operation, the input/output circuit 190 may output the 0th to 3rd DQ data dDQ0 to dDQ3 or the 0th to 3rd DQB data dDQ0B to dDQ3B as the input/output data DATA through the 0th to the 3rd input/output pins P0 to P3 based on the output data d_out and the operation mode. In some implementations, the output data d_out may include 0th to 3rd DQ data dDQ0 to dDQ3 and 0th to 3rd DQB data dDQ0B to dDQ3B. When the memory device 100 operates in the first mode, the input/output pins P0 to P3 may operate as the 0th to 3rd DQ pins DQ0 to DQ3 to output the 0th to 3rd DQ data. When the memory device 100 operates in the second mode, the input/output pins P0 to P3 may operate as the 0th to 3rd DQB pins DQ0B to DQ3B to output the 0th to 3rd DQB data dDQ0B to dDQ3B.

In the write operation, the input/output circuit 190 may receive the 0th to 3rd DQ data dDQ0 to dDQ3 or the 0th to 3rd DQB data dDQ0B to dDQ3B through the 0th to the 3rd input/output pins P0 to P3. When the memory device 100 operates in the first mode, the input/output circuit 190 may receive the 0th to 3rd DQ data dDQ0 to dDQ3, and when the memory device 100 operates in the second mode, the input-output circuit 190 may receive the 0th to 3rd DQB data dDQ0B to dDQ3B.

FIG. 3C is a diagram for describing a bounded fault condition. Referring to FIG. 3C, during a read operation in the first mode, the input/output circuit 190 may output the 0th to 3rd DQ data dDQ0 to dDQ3 through the 0th to 3rd input/output pins P0 to P3 for a burst length. Specifically, the input/output circuit 190 may output the 0th DQ data dDQ0 through the 0th input/output pin P0, may output the 1st DQ data dDQ1 through the first input/output pin P1, may output the 2nd DQ data dDQ2 through the 2nd input/output pin, and may output the 3rd DQ dDQ3 data through the 3rd input/output pin P3.

In addition, during the read operation in the second mode, the input/output circuit 190 may output the 0th to 3rd DQB data dDQ0B to dDQ3B through the 0th to 3rd input/output pins P0 to P3 during the burst length. Specifically, the input/output circuit 190 may output the 0th DQB data dDQ0B through the 0th input/output pin P0, may output the 1st DQB data dDQ1B through the 1st input/output pin P1, may output the 2nd DQB data dDQ2B through the 2nd input/output pin, and may output the 3rd DQB data dDQ3B through the 3rd input/output pin.

In some implementations, as shown in FIG. 3C, the burst length may be 16. In this case, each of the 0th to 3rd input/output pins P0 to P3 may transmit corresponding DQ data (e.g., dDQ0 to dDQ3) or corresponding DQB data (e. g., dDQ0B to dDQ3B) by 1 bit for each burst position (e.g., B0 to B15). Specifically, in the read operation in the first mode, the 0th to 3rd input/output pins P0 to P3 may operate as the 0th to 3rd DQ pins DQ0 to DQ3. In this case, for example, at the 0th burst position B0, the 0th input/output pin P0 may output one bit of the 0th DQ data dDQ0, the 1st input/output pin P1 may output one bit of the 1st DQ data dDQ1, the 2nd input/output pin P2 may output one bit of the 2nd DQ data dDQ2, and the 3rd input/output pin P3 may output one bit of the 3rd DQ data dDQ3.

In some implementations, each of the 0th to 3rd DQ data dDQ0 to dDQ3 and the 0th to 3rd DQB data dDQ0B to dDQ3B may be 16 bits.

The bounded fault condition may refer to a condition in which error bits generated in the input/output data DATA during a single burst length during a read operation are limited to affect only a specific number of input/output pins below. As the memory device 100 outputs the input/output data DATA while satisfying the bounded fault condition, error correction failure of an external device (e.g., a memory controller) may be prevented. When the number of input/output pins P0 to P3 is four as shown in FIG. 3B, the specific number may be two.

For example, during a read operation in the first mode, only bits of the 0th DQ data dDQ0 output through the 0th input/output pin P0 operating as the 0th DQ pin and bits of the 2nd DQ data dDQ2 output through the 2nd input/output pin P2 operating as the 2nd DQ pin may be error bits. In this case, the memory device 100 may satisfy the bounded fault condition.

For example, in a read operation in the second mode, when only bits of the 0th DQB data DQ0B output through the 0th input/output pin P0 operating as the 0th DQB pin and bits of the 1st DQB data DQ1B output through the 1st input/output pin P1 operating as the 1st DQB pin may be error bits. In this case, the memory device 100 may satisfy the bounded fault condition.

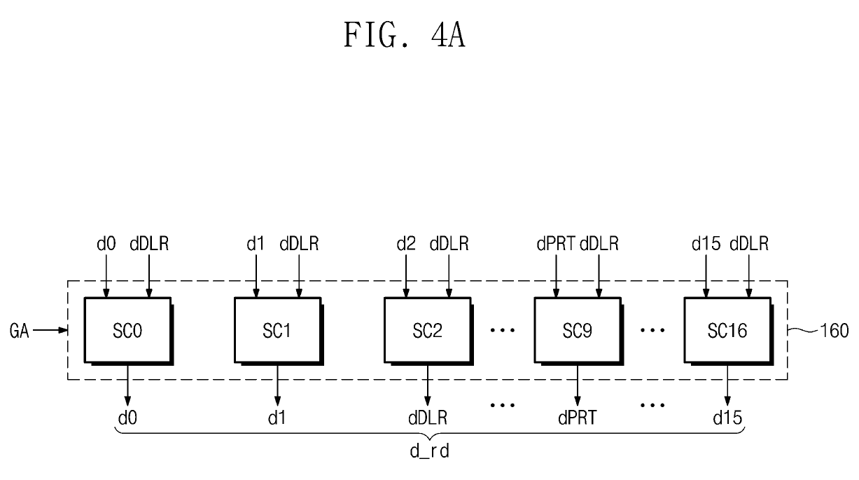

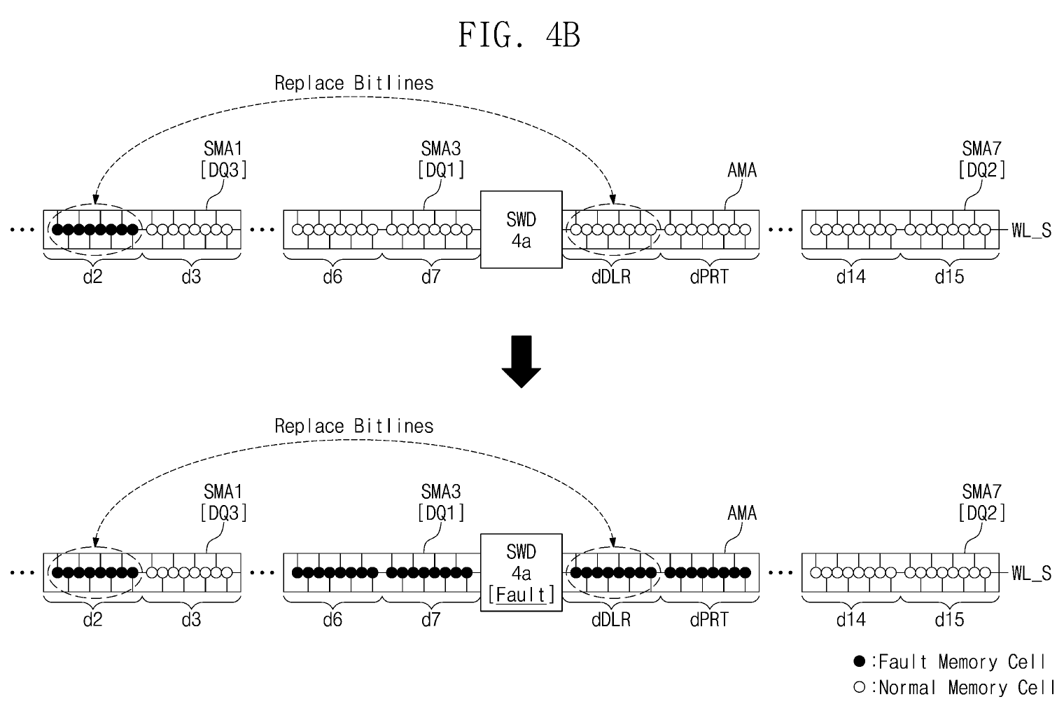

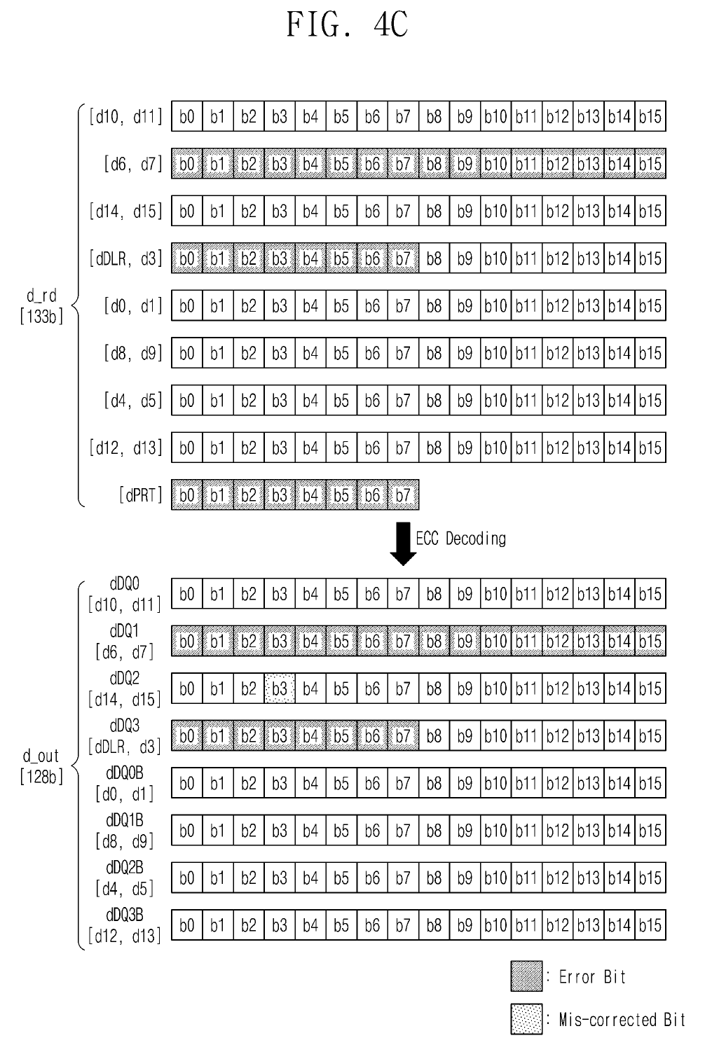

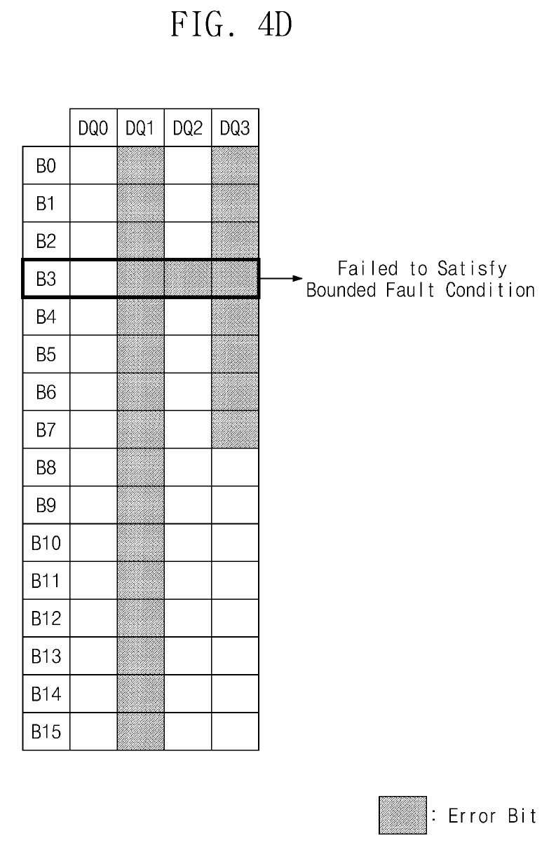

FIGS. 4A, 4B, 4C and 4D are diagrams for illustrating an example of operation of the memory device of FIG. 1 in the event of a failure of a sub-word line driver. FIG. 4A illustrates an example of the input/output gating circuit 160 of FIG. 3A. Referring to FIGS. 3A and 4A, the input/output gating circuit 160 may include a plurality of switching circuits SC0 to SC16. Each of the plurality of switching circuits SC0 to SC16 may be connected with bit lines of a region (e.g., R0, R1) of a corresponding sub-memory cell array (e.g., SMA0 to SMA7) or a region (e.g., R0, R1) of an auxiliary sub-memory cell array AMA. Each of the 0th to 16th switching circuits SC0 to SC16 may be connected to redundancy bit lines of the DLR region R_DLR of the auxiliary sub-memory cell array AMA. For example, the 0th switching circuit SC0 may be connected with bit lines of the 0th region R0 of the 0th sub-memory cell array SMA0, and the 1st switching circuit SC1 may be connected with the bit lines of the 1st region R1 of the 0th Sub-memory Cell Array SMA0.

In a read operation, the 0th switching circuit SC0 may receive the 0th data d0 and the DLR data dDLR, the 1st switching circuit SC1 may receive the 1st data d1 and the DLR data dDLR, the 2nd switching circuit SC2 may receive the 2nd data d2 and the DLR data dDLR, the 9th switching circuit SC9 may receive the parity data dPRT and the DLR data dDLR, and the 16th switching circuit SC16 may receive the 15th data d15 and the DLR data dDLR.

In a read operation, each of the switching circuits SC0 to SC16 may select output data from among the plurality of data received based on the gating control signal GA. For example, bit lines of an address corresponding to a read command among the bit lines of the 0th region R0 of the 1st sub-memory cell array SMA1 may be replaced with redundancy bit lines.

In this case, each of the 0th, 1st, 3rd to 8th, and 9th to 16th switching circuits SC0, SC1, SC3 to SC8, and SC9 to SC16 may output 0th, 1st, 3rd to 8th, and 9th to 15th data d0, d1, d3 to d8, and d9 to d15. The 9th switching circuit SC9 may output the parity data dPRT. The 2nd switching circuit SC2 may output DLR data dDLR received from bit lines of the DLR region R_DLR.

The plurality of data output from the switching circuits SC0 to SC16 may constitute the read data d_rd. In some implementations, the read data d_rd may be transmitted through the global input/output lines GIO. In some implementations, the read data d_rd may be 136 bits of data.

FIG. 4B is a diagram for illustrating error bits that occur in data when a failure of a sub-word line driver occurs. Referring to FIGS. 2A, 2B, and 4B, for example, selected bit lines among the bit lines of the 0th region R0 of the 1st sub-memory cell array SMA1 may be faulty bit lines. Accordingly, bit lines connected to the memory cells storing the 2nd data d2 may be replaced with redundancy bit lines of the DLR region R_DLR. Therefore, during the write operation in the first mode, the memory device 100 may store data received through the 3rd input/output pin P3 operating as the 3rd DQ pin DQ3 in the DLR region R_DLR as DLR data dDLR.

For example, after the faulty bit lines of the 0th region R0 of the 1st sub-memory cell array SMA1 are replaced with redundancy bit lines, a fault may occur in the 4th sub-word line driver SWD4a. The 4th sub-word line driver SWD4a may drive the selected word line WL_s of the 3rd sub-memory cell array SMA3 and the auxiliary sub-memory cell array AMA.

In this case, for example, due to a failure of the 4th sub-word line driver SWD4a, the memory cells connected to the selected word line WL_s of the 3rd sub-memory cell array SMA3 and the auxiliary sub-memory cell array AMA may become fault memory cells. Accordingly, the 6th data d6, the 7th data d7, the DLR data dDLR, and the parity data dPRT may include error bits.

FIG. 4C illustrates read data output by the input/output gating circuit of FIG. 4A and output data generated by the ECC decoder based on the read data. Referring to FIGS. 3A, 3B, 4A, 4B, and 4C, the read data d_rd may include 0th, 1st, 3rd to 8th, 9th to 15th data d0, d1, d3 to d8, d9 to d15, parity data dPRT, and DLR data dDLR selected by the switching circuits SC0 to SC16. The 6th data d6 and the 7th data d7 output from the 3rd sub-memory cell array SMA3, and the DLR data dDLR and the parity data dPRT output from the auxiliary sub-memory cell array AMA may include error bits.

The ECC decoder ECC-DEC may perform ECC decoding on the read data d_rd to generate the output data d_out. The output data d_out may include the 0th DQ data dDQ0 to the 3rd DQ data dDQ3, and the 0^{th} DQB data to the 3rd DQB data dDQ0B to dDQ3B.

The 0th DQ data dDQ0 may include the 10th data d10 and the 11th data d11 read out from the 5th sub-memory cell array SMA5, the 1st DQ data dDQ1 may include the 6th data d6 and the 7th data d7 read out from the 3rd sub-memory cell array SMA3, and the 2nd DQ data dDQ2 may include the 14th data d14 and the 15th data d15 read out from the 7th sub-memory cell array SMA7. At this time, the upper 8 bits of each of the 0th to the 2nd DQ data dDQ0 to dDQ2 may be data d10, d6, and d14 read out from the 0th region R0 of the corresponding sub-memory cell array, and the lower 8 bits may be data d11, d7, and d15 read out from the 1st region R1 of the corresponding sub-memory cell array. The 3rd DQ data dDQ3 may include the DLR data dDLR read from the DLR region R_DLR of the auxiliary sub-memory cell array AMA and the 3rd data d3 read from the 1st region R1 of the 1st sub-memory cell array SMA1. In this case, the upper 8 bits of the 3rd DQ data dDQ3 may be the DLR data dDLR, and the lower 8 bits may be the 3rd data d3.

The 0th DQB data dDQ0B may include the 0th data d0 and the 1st data d1 read out from the 0th sub-memory cell array SMA0, the 1st DQB data DDQ1B may include the 8th data d8 and the 9th data d9 read out from the 4th sub-Memory Cell Array SMA4, the 2nd DQB data dDQ2B may include the 4th data d4 and the 5th data d5 read out from the 2nd sub-memory cell array SMA2, and the 3rd DQB data cDQ3B may include the 10th data d10 and the 11th data d11 read out from the 6th sub-memory cell array SMA6. At this time, the upper 8 bits of each of the 0th to 3rd DQB data dDQ0B to dDQ3B may be data d0, d8, d4, and d12 read from the 0th region R0 of the corresponding sub-memory cell array, and the lower 8 bits may be data d1, d9, d5, and d13 read from the 1st region R1 of the corresponding sub -memory cell arrangement.

Since the read data d_rd includes one or more error bits, the error may not be corrected by ECC decoding. Accordingly, the read data d_rd may include a plurality of error bits of the 6th data d6, the 7th data d7, and the DLR data dDLR. The parity data dPRT may include a plurality of error bits. Accordingly, the ECC decoder ECC-DEC may perform mis-correction when performing ECC decoding. That is, the ECC decoder ECC-DEC may determine a bit in which no error has occurred among the bits of the read data d_rd as an error bit and may change a bit value of the bit. For example, the ECC decoder ECC-DEC may perform erroneous correction on the 3rd bit b3 of the 14th data d14 to generate the 2nd DQ data dDQ2. Accordingly, the 3rd bit b3 of the 2nd DQ data dDQ2 may be an error bit.

FIG. 4D is a diagram for describing input/output data output by the input/output circuit of FIG. 3A in the read operation in the first mode. Referring to FIGS. 3A, 4C, and 4D, in the read operation of the first mode, the input/output pins P0 to P3 of the input/output circuit 190 may operate as DQ pins DQ0 to DQ3. Accordingly, the input/output circuit 190 may output the 0th to 3rd DQ data dDQ0 to dDQ3 during the burst length including the 0th to 15th burst positions B0 to B15. Specifically, the input/output circuit 190 may output the 0th DQ data dDQ0 through the 0th input/output pin P0 that operates as the 0th DQ pin DQ0, output the 1st DQ data dDQ1 through the 1st input/output pin P1 that operates as the 1st DQ pin DQ1, output the 2nd DQ data dDQ2 through the 2nd input/output pin P2 that operates as the 2nd DQ pin DQ2, and output the 3rd DQ data dDQ3 through the 3rd input/output pin P3 that operates as the 3rd DQ pins DQ3.

In this case, at the 3rd burst position B3, the 1st to 3rd DQ pins DQ1 to DQ3 may output 3rd bits b3 of the 1st to 3rd DQ data dDQ1 to dDQ3. At the 3rd burst position B3, three error bits may be output through the DQ pins DQ0 to DQ4. Accordingly, the memory device 100 may not satisfy the bounded fault condition.

As described above, after the input/output gating circuit 160 is implemented as shown in FIG. 4A and the faulty bit lines are replaced with redundancy bit lines, a fault may occur in a sub-word line driver (e.g., SWD4a) that drives the auxiliary sub-memory cell array AMA. In this case, the memory device 100 may not satisfy the bounded fault condition.

According to some implementations of the present disclosure, the memory device 100 may change a storage location of input/output data DATA based on a location of a sub-memory cell array including faulty bit lines replaced with redundancy bit lines during a write operation. In addition, the memory device 100 may transfer data read from the changed storage location to an external device (e.g., a memory controller) during a read operation. Accordingly, the memory device 100 may satisfy the bounded fault condition even when a defect occurs in the sub-word line driver (e.g., SWD4a) that drives the auxiliary sub-memory cell array AMA. The operation of the memory device 100 according to some implementations of the present disclosure will be described in more detail with reference to the following drawings.

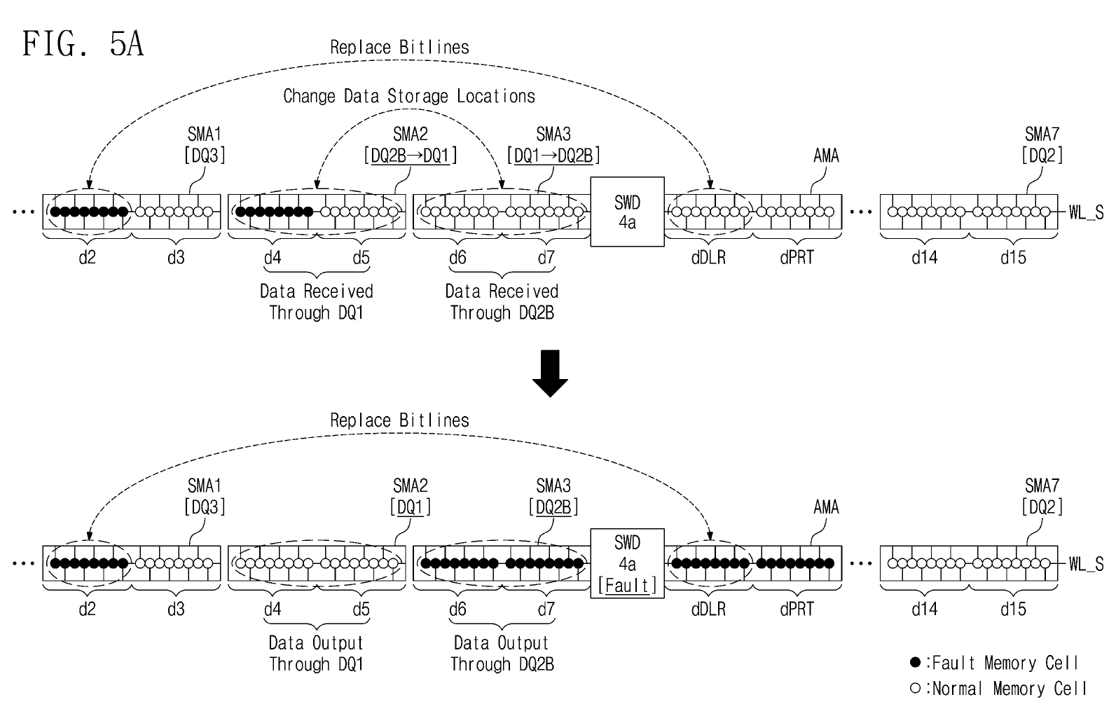

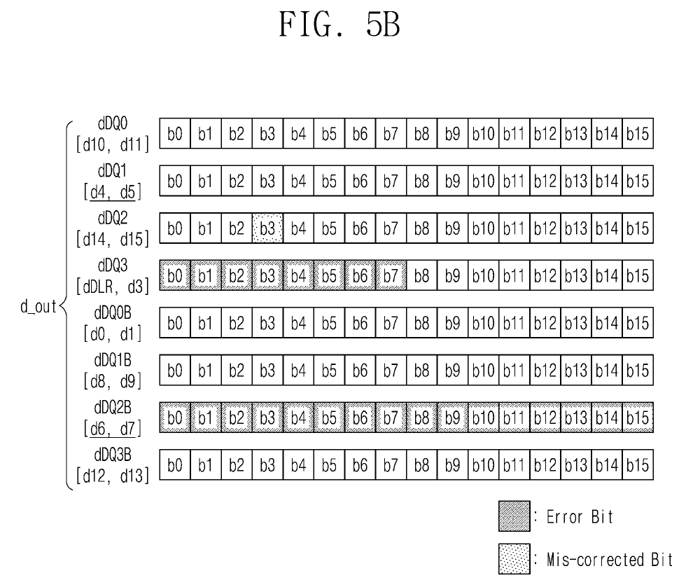

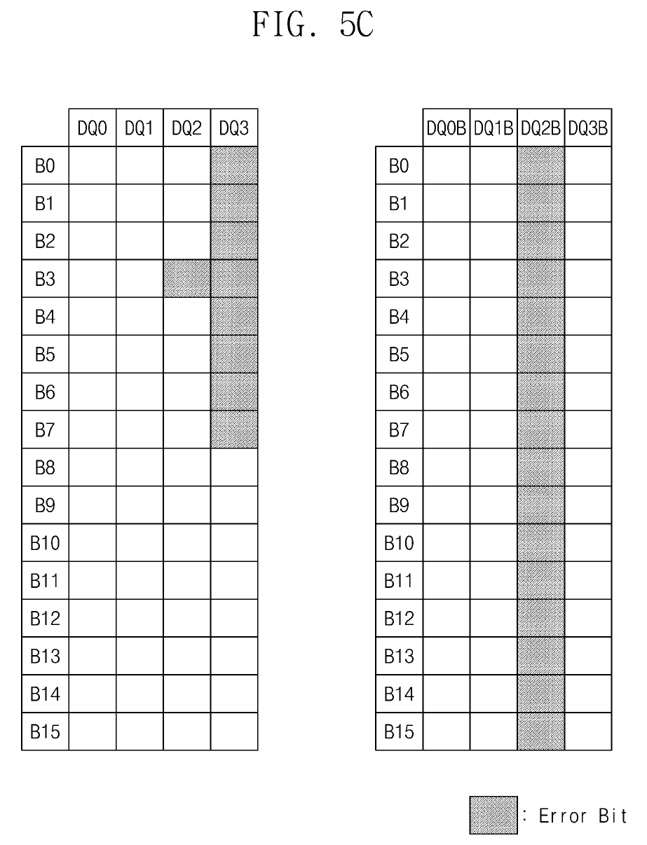

FIGS. 5A, 5B and 5C are diagrams for illustrating an operation of a memory device according to some implementations of the present disclosure. Referring to FIGS. 1, 3A, and 5A, for example, bit lines selected based on the address ADDR among the bit lines of the 0th region R0 of the 1st sub-memory cell array SMA1 may be faulty bit lines. Accordingly, bit lines connected to the memory cells storing the 2nd data d2 may be replaced with redundancy bit lines of the DLR region R_DLR. Therefore, during the write operation in the first mode, the memory device 100 may store data received through the 3rd input/output pin P3 operating as the 3rd DQ pin DQ3 in the DLR region R_DLR as DLR data dDLR.

According to some implementations of the present disclosure, when the sub-memory cell array (e.g., SMA1) including faulty bit lines corresponds to a DQ pin (e.g., DQ3) and is not a sub-memory cell array (e.g., SMA3) adjacent to the auxiliary sub-memory cell array AMA, the memory device 100 may map the 1st DQ pin DQ1 to the second sub-memory cell array SMA2 and map the 2nd DQB pin DQ2B to the 3rd sub-memory cell array SMA3. That is, the memory device 100 may change input/output pins corresponding to the 2nd sub-memory cell array SMA2 and the 3rd sub-memory cell array SMA3.

As a more detailed example, the memory device 100 may change a storage location of data received through the 1st DQ pin DQ1 from the 3rd sub-memory cell array SMA3 to the 2nd sub-memory cell array SMA2. In addition, the memory device 100 may change a storage location of data received through the 2nd DQB pin DQ2B from the 2nd sub-memory cell array SMA2 to the 3rd sub-memory cell array SMA3. Accordingly, the memory device 100 may change the mapping relationship between the 2nd sub-memory cell array SMA2 and the 3rd sub-memory cell array SMA3 and the 1st DQ pin DQ1 and the 2nd DQB pin DQ2B.

Accordingly, during the write operation in the first mode, the memory device 100 may store the data received through the 1st input/output pin P1 operating as the 1st DQ pin DQ1 in the 2nd sub-memory cell array SMA2 as the 4th data d4 and the 5th data d5. The memory device 100 may store data corresponding to the 3rd address region AR3 in the 2nd sub-memory cell array SMA2 corresponding to the 2nd address region AR2. In addition, during the write operation in the second mode, the memory device 100 may store data received through the 2nd input/output pin P2 operating as the 2nd DQB pin DQ2B in the 3rd sub-memory cell array SMA3 as the 6th data d6 and the 7th data d7. In other words, the memory device 100 may store data corresponding to the 2nd address region AR2 in the 3rd sub-memory cell array SMA3 corresponding to the 3rd address region AR3.

For example, after the faulty bit lines of the 1st sub-memory cell array SMA1 are replaced with redundancy bit lines, a fault may occur in the 4th sub-word line driver SWD4a. The 4th sub-word line driver SWD4a may drive the selected word line WL_s of the 3rd sub-memory cell array SMA3 and the auxiliary sub-memory cell array AMA.

In this case, for example, due to a failure of the 4th sub-word line driver SWD4a, the memory cells connected to the selected word line WL_s of the 3rd sub-memory cell array SMA3 and the auxiliary sub-memory cell array AMA may become defective memory cells. Accordingly, the 6th data d6, the 7th data d7, the DLR data dDLR, and the parity data dPRT may include error bits.

FIG. 5B illustrates output data generated by the ECC decoder of FIG. 3B in a read operation for the memory cells of FIG. 5A. Referring to FIGS. 3A, 3B, 5A, and 5B, the output data d_out may include 0th to 3rd DQ data dDQ0 to dDQ3, and 0th DQB data to 3rd DQB data dDQ0B to dDQ3B. In the read operation in the first mode, the input/output circuit 190 may output the 0th to the 3rd DQ data dDQ0 to dDQ3 through the 0th to 3rd input/output pins P0 to P3, and in the read operation in a second mode, the input-output circuit 190 may also output the 0th and the 3rd DQB data dDQ0B to dDQ3B through the 0th and 3rd input/output fins P0 toP3.

As described above with respect to FIG. 5A, the memory device 100 may store data received via the 1st DQ pin DQ1 in the 2nd sub-memory cell array SMA2 and store data received via a 2nd DQB pin DQ2 in the 3rd sub-memory cell array SMA3 after faulty bit lines of the 1st sub-memory cell array SMA1 are replaced with redundancy bit lines. Accordingly, in some implementations, the 1st DQ data dDQ1 may include the 4th data d4 and the 5th data d5 and may not include error bits. The 2nd DQB data dDQ2B may include the 6th data d6 and the 7th data d7 and may include error bits.

For example, the ECC decoder ECC-DEC may perform mis-correction on the 3rd bit b3 of the 14th data d14 to generate the 2nd DQ data dDQ2. Accordingly, the 3rd bit b3 of the 2nd DQ data dDQ2 may be an error bit.

FIG. 5C is a diagram for describing input/output data output by the input/output circuit of FIG. 3A in a read operation. Referring to FIGS. 3A, 5A, 5B, and 5C, and 5C, in the read operation in the first mode, the input/output pins P0 to P3 of the input/output circuit 190 may operate as DQ pins DQ0 to DQ3. Accordingly, during the burst length, the input/output circuit 190 may output the 0th DQ data dDQ0 through the 0th input/output pin P0 that operates as the 0th DQ pin DQ0, output the 1st DQ data dDQ1 through the 1st input/output pin P1 that operates as the 1st DQ pin DQ1, output the 2nd DQ data dDQ2 through the 2nd input/output pin P2 that operates as the 2nd DQ pin DQ2, and output the 3rd DQ data dDQ3 through the 3rd input/output pins P3 that operates as the 3rd DQ pins DQ3.

In such cases, since the 1st DQ data dDQ1 does not include an error bit, the bits output through the 0th to 3rd DQ pins DQ0 to DQ3 at the 3rd burst position B3 may include two error bits. That is, during the burst length, the error bits may be output only through the 2nd DQ pin DQ2 or the 3rd DQ pin DQ3. Therefore, the memory device 100 may satisfy the bounded fault condition.

In addition, in the read operation in the second mode, the input/output pins P0 to P3 of the input/output circuit 190 may operate as the DQB pins DQ0B to DQ3B. Accordingly, during the burst length, the input/output circuit 190 may output the 0th DQB data dDQ0B through the 0th input/output pin P0 operating as the 0th DQB pin DQ0B, output the 1st DQB data dDQ1B through the 1st input/output pin P1 operating as the 1st DQB pin DQ1B, output the 2nd DQB data dDQ2B through the 2nd input/output pin P2 operating as the 2nd DQB pin DQ2B, and output the 3rd DQB data dDQ3B through the 3rd input/output pins P3 operating as the 3rd DQB pins DQ3B.

In this case, only the 2nd DQB data dDQ2B may include error bits. Accordingly, during the burst length, error bits may be output only through the 2nd DQB pin DQ2B. Therefore, the memory device 100 may satisfy the bounded fault condition.

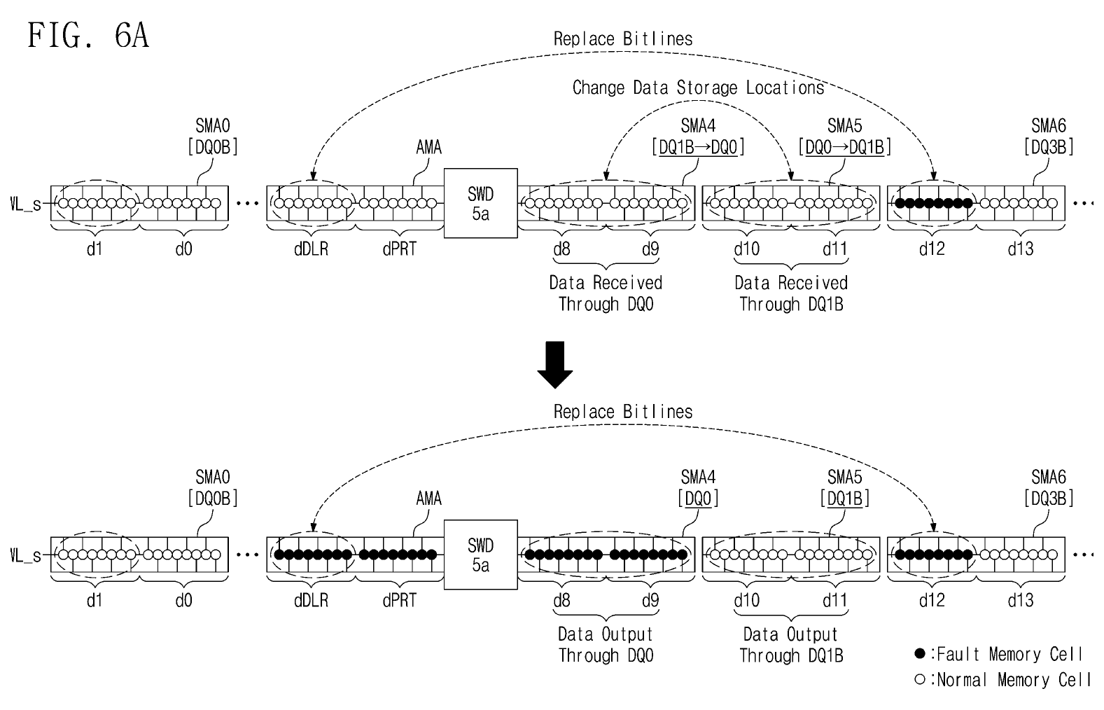

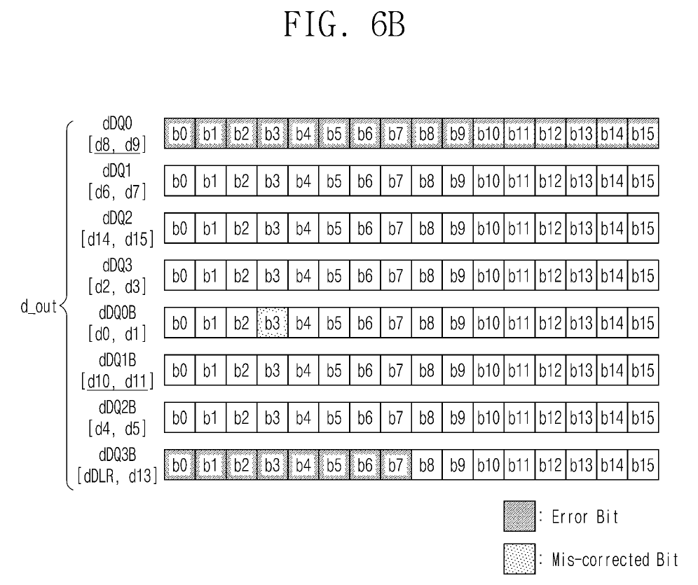

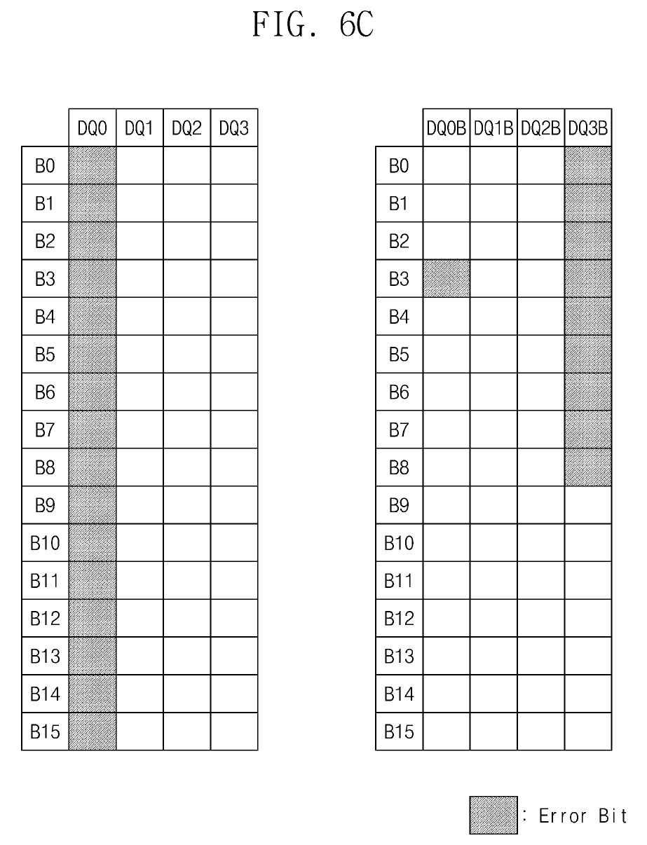

FIGS. 6A, 6B and 6C are diagrams for illustrating an operation of a memory device according to some implementations of the present disclosure. Referring to FIGS. 1, 3A, and 6A, for example, selected bit lines based on the address ADDR among the bit lines of the 0th region R0 of the 6th sub-memory cell array SMA6 may be faulty bit lines. Accordingly, bit lines connected to the memory cells storing the 12th data d12 may be replaced with redundancy bit lines of the DLR region R_DLR. Therefore, during the write operation in the second mode, the memory device 100 may store data received through the 3rd input/output pin P3 operating as the 3rd DQB pin DQ3B in the DLR region R_DLR as DLR data dDLR.

For example, a sub-memory cell array (e.g., SMA1) including faulty bit lines may correspond to a DQB pin (e.g., DQ3B). In addition, the sub-memory cell array (e.g., SMA1) including faulty bit lines may not be a sub-memory cell array (e.g., SMA4) corresponding to a DQB pin (e.g., DQ1B) among sub-memory cell arrays (e.g., SMA3, SMA4) adjacent to the auxiliary sub-memory cell array AMA. In this case, the memory device 100 may map the 4th sub-memory cell array SMA4 to the 0th DQ pin DQ0 and map the 5th sub-memory cell array SMA5 to the 1st DQB pin DQ1B. That is, the memory device 100 may change input/output pins corresponding to the 4th sub-memory cell array SMA4 and the 5th sub-memory cell array SMA5.

As a more detailed example, the memory device 100 may change a storage location of data received through the 1st DQB pin DQ1B from the 4th sub-memory cell array SMA4 to the 5th sub-memory cell array SMA5. In addition, the memory device 100 may change a storage location of data received through the 0th DQ pin DQ0 from the 5th sub-memory cell array SMA5 to the 4th sub-memory cell array SMA4. Accordingly, the memory device 100 may change the mapping relationship between the 4th sub-memory cell array SMA4 and the 5th sub-memory cell array SMA5 and the 1st DQB pin DQ1B and the 0th DQ pin DQ0.

Accordingly, during the write operation in the first mode, the memory device 100 may store, in the 4th sub-memory cell array SMA4, data received through the 0th input/output pin P0 operating as the 0th DQ pin DQ0 as the 8th data d8 and the 9th data d9. In other words, the memory device 100 may store data corresponding to the 6th address region AR5 in the 4th sub-memory cell array SMA4 corresponding to the 5th address region R5. In addition, during the write operation in the second mode, the memory device 100 may store data received through the 1st input/output pin P1 operating as the 1st DQB pin DQ1B in the 5th sub-memory cell array SMA5 as the 10th data d10 and the 11th data d11. In other words, the memory device 100 may store data corresponding to the 5th address region AR5 in the 5th sub-memory cell array SMA5 corresponding to the 6th address region AR6.

For example, after the faulty bit lines of the 6th sub-memory cell array SMA6 are replaced with redundancy bit lines, a fault may occur in the 5th sub-word line driver SWD5a. The 5th sub-word line driver SWD5a may drive the selected word line WL_s of the auxiliary sub-memory cell array AMA and the 4th sub-memory cell array SMA.

In such cases, for example, due to a failure of the 5th sub-word line driver SWD5a, memory cells connected to the selected word line WL_s of the auxiliary sub-memory cell array AMA and the 4th sub-memory cell array SMA4 may become fault memory cells. Accordingly, the 8th data d8, the 9th data d9, the DLR data dDLR, and the parity data dPRT may include error bits.

FIG. 6B illustrates output data generated by the ECC decoder of FIG. 3B in a read operation for the memory cells of FIG. 6A. Referring to FIGS. 3A, 3B, 6A, and 6B, the output data d_out may include 0th to 3rd DQ data dDQ0 to dDQ3, and 0th DQB data to 3rd DQB data dDQ0B to dDQ3B. In the read operation in the first mode, the input/output circuit 190 may output the 0th to the 3rd DQ data dDQ0 to dDQ3 through the 0th to 3rd input/output pins P0 to P3, and in the read operation in a second mode, the input-output circuit 190 may also output the 0th and the 3rd DQB data dDQ 0B to dDQ 3B through the 0th and 3rd input/output fins P0 to P3.

As described above with respect to FIG. 6A, the memory device 100 may store data received through the 0th DQ pin DQ0 in the 4th sub-memory cell array SMA4 and store data received through a 1st DQB pin DQ1B in the 5th sub-memory cell array SMA5 after the faulty bit lines of the 6th sub-memory cell array SMA6 are replaced with redundancy bit lines. Accordingly, the 1st DQB data dDQ1B may include the 10th data d10 and the 11th data d11 and may not include error bits. The 0th DQ data dDQ0 may include the 8th data d8 and the 9th data d9 including error bits.

For example, the ECC decoder ECC-DEC may perform mis-correction on the 3rd bit b3 of the 0th data d0 to generate the 0th DQB data dDQ0B. Accordingly, the 3rd bit b3 of the 0th DQB data dDQ0B may be an error bit.

FIG. 6C is a diagram for describing input/output data output by the input/output circuit of FIG. 3A in a read operation. Referring to FIGS. 3A, 6A, 6B, and 6C, in the read operation in the first mode, the input/output pins P0 to P3 of the input/output circuit 190 may operate as DQ pins DQ0 to DQ3. Accordingly, during the burst length, the input/output circuit 190 may output the 0th DQ data dDQ0 through the 0th input/output pin P0 that operates as the 0th DQ pin DQ0, output the 1st DQ data dDQ1 through the 1st input/output pinP1 that operates as the 1st DQ pin DQ1, output the 2nd DQ data dDQ2 through the 2nd input/output pin P2 that operates as the 2nd DQ pin DQ2, and output the 3rd DQ data dDQ3 through the 3rd input/output pins P3 that operates as the 3rd DQ pins DQ3.

In this case, only the 0th DQ data dDQ0 may include error bits. Accordingly, during the burst length, error bits may be output only through the 0th DQ pin DQ0. Therefore, the memory device 100 may satisfy the bounded fault condition.

In addition, in the read operation in the second mode, the input/output pins P0 to P3 of the input/output circuit 190 may operate as the DQB pins DQ0B to DQ3B. Accordingly, during the burst length, the input/output circuit 190 may output the 0th DQB data dDQ0B through the 0th input/output pin P0 operating as the 0th DQB pin DQ0B, output the 1st DQB data dDQ1B through the 1st input/output pin P1 operating as the 1st DQB pin DQ1B, output the 2nd DQB data dDQ2B through the 2nd input/output pin P2 operating as the 2nd DQB pin DQ2B, and output the 3rd DQB data dDQ3B through the 3rd input/output pins P3 operating as the 3rd DQB pins DQ3B.

In this case, even if mis-correction by the ECC decoder ECC-DEC is performed, the error bits may be output only through the 0th DQB pin DQ0B or the 3rd DQB pin DQ3B during the burst length. Therefore, the memory device 100 may satisfy the bounded fault condition.

As described above with reference to FIGS. 5A, 5B, 5C, 6A, 6B, and 6C, according to some implementations of the present disclosure, the memory device 100 may change a storage location of data received through input/output pins and corresponding to normal bit lines, based on an address of bit lines replaced with redundancy bit lines. Accordingly, the memory device 100 may satisfy the bounded fault condition even when a sub-word line driver failure that drives word lines of the auxiliary sub-memory cell array AMA occurs.

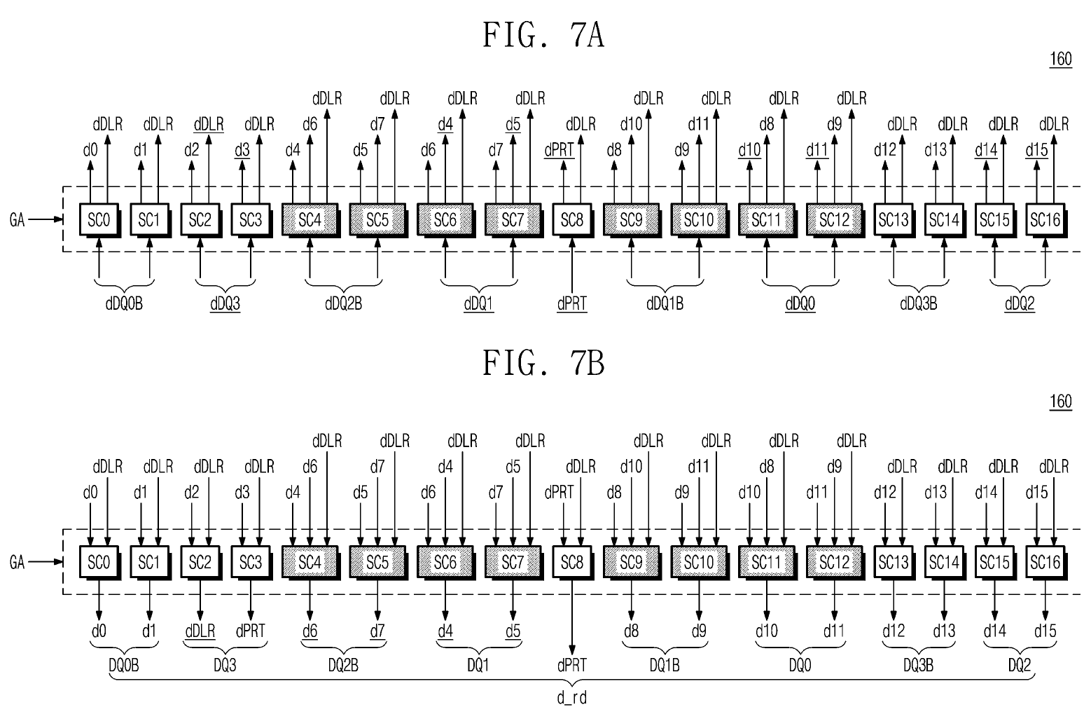

FIGS. 7A and 7B are block diagrams for illustrating the input/output gating circuit of FIG. 3A. Specifically, FIG. 7A is a block diagram for describing an operation of the input/output gating circuit 160 during a write operation, and FIG. 7B is a block diagram to describe an operation of the output/output gating circuit 160 during a read operation.

Referring to FIGS. 1, 2A, 3A, and 7A, the input/output gating circuit 160 may include a plurality of switching circuits SC0 to SC16. In a write operation, the 0th switching circuit SC0 may be selectively connected with bit lines of the 0th region R0 of the 0th sub-memory cell array SMA0 or bit lines of the DLR region R_DLR of the auxiliary sub-memory cell array AMA. The 0th switching circuit SC0 may receive 8 bits of the 0th DQB data dDQ0B received through the 0th DQB pin DQ0B. At this time, the 8 bits may be bits received through the 0th DQB pin DQ0B during eight burst positions (e.g., B0 to B7). The 0th switching circuit SC0 may transmit 8 bits of the received 0th DQB data dDQ0B to the 0th region R0 or the DLR region R_DLR of the 0th sub-memory cell array SMA0 in response to the gating control signal GA.

For example, when bit lines of the 0th region R0 of the 0th sub-memory cell array SMA0 are replaced with redundancy bit lines, the 0th switching circuit SC0 may output 8 bits of the 0th DQB data dDQ0B as DLR data dDLR data and transmit the same to the DLR region R_DLR. For example, when the bit lines of the 0th region R0 of the 0th sub-memory cell array SMA0 are normal bit lines, the 0th switching circuit SC0 may output 8 bits of the 0th DQB data dDQ0B as the 0th data d0 data and transmit the same to the 0th regionR0 of the 0st sub-memory cell array SMA0.

The 1st switching circuit SC1 may be selectively connected with bit lines of the 1st region R1 of the 0th sub-memory cell array SMA0 or bit lines of the DLR region R_DLR of the auxiliary sub-memory cell array AMA. The 1st switching circuit SC1 may receive 8 bits of the 0th DQB data dDQ0B received through the 0th DQB pin DQ0B by the 0th switching circuit SC0. At this time, the 8 bits may be bits received through the 0th DQB pin DQ0B during eight burst positions (e.g., B8 to B15). The 1st switching circuit SC1 may operate similarly to the 0th switching circuit SC0. The 1st switching circuit SC1 may output 8 bits of the 0th DQB data dDQ0B as the 1st data d1 or the DLR data dDLR and transfer the 8 bits to the 1st region R1 or the DLL region R_DLR of the 0th sub-memory cell array SMA0.

The 2nd, 3rd, 8th, and 13th to 16th switching circuits SC2, SC3, SC8, and SC13 to SC16 may operate similarly to the 0th switching circuit SC0 and the 1st switching circuit SC1.

Specifically, the 2nd and 3rd switching circuits SC2 and SC3 may be selectively connected with the 1st sub-memory cell array SMA1 and the DLR region R_DLR, and may transfer the 1st DQB data dDQ1 received through the 1st DQ pin DQ1 to the 1st sub-Memory Cell Array SMA1 or the DLR region R_DLR. The 8th switching circuit SC8 may be selectively connected to the DLR region R_DLR and the parity region R_PRT of the auxiliary sub-memory cell array AMA and may transfer the parity data dPRT to the DLR regions R_DLR or the parity regions R_PRT. The 13th and 14th switching circuits SC13 and SC14 may be selectively connected with the 6th sub-memory cell array SMA6 and the DLR region R_DLR, and may transfer the 3rd DQB data dDQ3B received through the 3rd DQB pin DQ3B to the 6th sub-memory cell array SMA6 or the DLR region R_DLR. The 15th and 16th switching circuits SC15 and SC16 may be selectively connected with the 7th sub-memory cell array SMA7 and the DLR region R_DLR, and may transfer the 2nd DQ data dDQ2 received through the 2nd DQ pin DQ2 to the 7th sub-memory cell array SMA7 or the DLR region R_DLR.

The 4th switching circuit SC4 may be selectively connected with bit lines of the 0th region R0 of the 2nd sub-memory cell array SMA2, bit lines of the 0th region R0 in the 3rd sub-memory cell array SMA3, or bit lines of the DLR region R_DLR in the auxiliary sub-memory cell array AMA. The 4th switching circuit SC4 may receive 8 bits of 2nd DQB data dDQ2B received through the 2nd DQB pin DQ2. At this time, the 8 bits may be bits received through the 0th DQB pin DQ0B during eight burst positions (e.g., B0 to B7). In response to the gating control signal GA, the 4th switching circuit SC4 may transfer 8 bits of the 2nd DQB data dDQ2B to the 0th region R0 of the 2nd sub-memory cell array SMA2, the 0th regions R0 of the 3rd sub-memory cell array SMA3, or the DLR region R_DLR.

For example, the bit lines of the 1st sub-memory cell array SMA1, the 0th region R0 of the 2nd sub-memory cell array SMA2, the 5th sub-memory cell array SMA5, and the 7th sub-memory cell array SMA7 may be normal bit lines (i.e., not replaced with redundancy bit lines). In this case, the 4th switching circuit SC4 may output 8 bits of the 2nd DQB data dDQ2B as the 4th data d4 and transmit the same to the 3rd sub-memory cell array SMA3.

For example, bit lines of the 1st sub-memory cell array SMA1, the 5th sub-memory cell array SMA5, and the 7th sub-memory cell array SMA7 may be normal bit lines, and the 0th region R0 bit lines of the 2nd sub-memory cell array SMA2 may be replaced with redundancy bit lines. In this case, the 4th switching circuit SC4 may output 8 bits of the 2nd DQB data dDQ2B as the DLR data dDLR and transmit the same to the auxiliary sub-memory cell array AMA.

For example, as shown in FIG. 5A, bit lines of the 0th region R0 of the 1st sub-memory cell array SMA1 may be replaced with redundancy bit lines. In this case, in response to the gating control signal GA, the 4th switching circuit SC4 may output 8 bits of the 2nd DQB data dDQ2B as the 6th data d6 and transmit the same to the 3rd sub-memory cell array SMA3.

The 5th switching circuit SC5 may be selectively connected with bit lines of the 1st region R1 of the 2nd sub-memory cell array SMA2, bit lines of the 3rd sub-memory cell array SMA3 in the 1st region R1, or bit lines of the DLR region R_DLR of the auxiliary sub-memory cell array AMA. The 6th switching circuit SC6 may be selectively connected with bit lines of the 0th region R0 of the 3rd sub-memory cell array SMA3, bit lines of the 0th region R0 in the 2nd sub-memory cell array SMA2, or bit lines of the DLR region R_DLR in the auxiliary sub-memory cell array AMA, and the 7th switching circuit SC7 may be selectively connected to bit lines of the 1st region R1 in the 3rd sub-memory cell array SMA3, bit lines in the 1st region R1 in the 2nd sub -memory cell arrangement SMA2, or the bit lines in the DLR region R_DLR of the auxiliary sub-memory cell array AMA.

The 5th to 7th switching circuits SC5 to SC7 may operate similarly to the 4th switching circuit SC4. The 5th switching circuit SC5 may receive 8 bits of the 2nd DQB data dDQ2B (e.g., bits received during the burst positions B8 to B15) and output the 5th data d5, the 7th data d7, or the DLR data dDLR in response to the gating control signal GA. The 6th switching circuit SC6 may receive eight bits (e.g., bits received during the burst positions B0 to B7) of the 1st DQ data dDQ1, and output the eight bits as the 6th data d6, the 4th data d4, or the DLR data dDLR in response to the gating control signal GA. The 7th switching circuit SC7 may receive eight bits (e.g., bits received during the burst positions B8 to B15) of the 1st DQ data dDQ1, and output the eight bits as the 7th data d7, the 5th data d5, or the DLR data dDLR in response to the gating control signal GA.

In some implementations, the memory device 100 may change the storage positions of the 2nd DQB data dDQ2B and the 1st DQ data dDQ1 by controlling the 4th to 7th switching circuits SC4 to SC7.

The 9th switching circuit SC9 may be selectively connected with bit lines of the 0th region R0 of the 4th sub-memory cell array SMA4, bit lines of the 0th region R0 in the 5th sub-memory cell array SMA5, or bit lines of the DLR region R_DLR in the auxiliary sub-memory cell array AMA. The 9th switching circuit SC9 may receive 8 bits of the 1st DQB data dDQ1B received through the 1st DQB pin DQ1B. At this time, the 8 bits may be bits received through the 1st DQB pin DQ1B during eight burst positions (e.g., B0 to B7). In response to the gating control signal GA, the 9th switching circuit SC9 may transfer 8 bits of the 1st DQB data dDQ1B to the 0th region R0 of the 4th sub-memory cell array SMA4, the 0th regions R0 of the 5th sub-memory cell array SMA5, or the DLR region R_DLR.

For example, the bit lines of the 0th sub-memory cell array SMA0, the 2nd sub-memory cell array SMA2, the 0th region R0 of the 4th sub-memory cell array SMA4, and the 6th sub-memory cell array SMA6 may be normal bit lines (i.e., not replaced with redundancy bit lines). In this case, the 9th switching circuit SC9 may output the upper 8 bits of the 1st DQB data dDQ1B as the 8th data d8 and transmit the same to the 4th sub-memory cell array SMA4.

For example, bit lines of the 0th sub-memory cell array SMA0, the 2nd sub-memory cell array SMA2, and the 6th sub-memory cell array SMA6 are normal bit lines, and the 0th region R0 bit lines of the 4th sub-memory cell array SMA4 may be replaced with redundancy bit lines. In this case, the 9th switching circuit SC9 may output the upper 8 bits of the 1st DQB data dDQ1B as the DLR data dDLR and transmit the DLR data to the auxiliary sub-memory cell array AMA.

For example, as shown in FIG. 6A, bit lines of the 0th region R0 of the 6th sub-memory cell array SMA6 may be replaced with redundancy bit lines. In this case, the 9th switching circuit SC9 may output the upper 8 bits of the 1st DQB data dDQ1B as the 10th data d10 and transmit the same to the 5th sub-memory cell array SMA5.

The 10th switching circuit SC10 may be selectively connected with bit lines of the 1st region R1 of the 4th sub-memory cell array SMA4, bit lines of the 1st region R1 of a 5th sub-memory cell array SMA5, or bit lines of the DLR region R_DLR of the auxiliary sub-memory cell array AMA. The 11th switching circuit SC11 may be selectively connected with bit lines of the 0th region R0 of the 5th sub-memory cell array SMA5, bit lines of the 0th region R0 in the 4th sub-memory cell array SMA4, or bit lines of the DLR region R_DLR in the auxiliary sub-memory cell array AMA, and the 12th switching circuit SC12 may be selectively connected to bit lines of the 1st region R1 in the 5th sub-memory cell array BMA5, bit line of the 1st region R1 in the 4th sub -memory cell arrangement SMA4, and bit lines of the DLR region R_DLR in the auxiliary Sub-memory Cell Array AMA.

The 10th to 12th switching circuits SC10 to SC12 may operate similarly to the 9th switching circuit SC9. The 10th switching circuit SC10 may receive eight bits (e.g., bits received during the burst positions B8 to B15) of the 1st DQB data dDQ1B, and output the eight bits as the 9th data d9, the 11th data d11, or the DLR data dDLR in response to the gating control signal GA. The 11th switching circuit SC11 may receive eight bits (e.g., bits received during the burst positions B0 to B7) of the 0th DQ data dDQ0, and output the eight bits as the 10th data d10, the 8th data d8, or the DLR data dDLR in response to the gating control signal GA. The 12th switching circuit SC12 may receive eight bits (e.g., bits received during the burst positions B8 to B15) of the 0th DQ data dDQ0, and output the eight bits as the 11th data d11, the 9th data d9, or the DLR data dDLR in response to the gating control signal GA.

In some implementations, the memory device 100 may change the storage locations of the 1st DQB data dDQ1B and the 0th DQ data dDQ0 by controlling the 9th to 12th switching circuits SC9 to SC12.

That is, during a write operation, each of the switching circuits SC0 to SC16 may operate as a demultiplexer.

For example, as shown in FIG. 5A, bit lines of the 0th region R0 of the 1st sub-memory cell array SMA1 may be replaced with redundancy bit lines. In this case, in the write operation in the first mode, the input/output pins P0 to P3 of the input/output gating circuit 160 may operate as the DQ pins DQ0 to DQ3. Accordingly, the input/output gating circuit 160 may receive the 0th to 3rd DQ data dDQ0 to dDQ3 and the parity data dPRT.

In this case, the 2nd switching circuit SC2 may output 8 bits of the 3rd DQ data dDQ3 as the DLR data dDLR. The 3rd switching circuit SC3 may output 8 bits of the 3rd DQ data dDQ3 as the 3rd data d3. The 6th switching circuit SC6 and the 7th switching circuit SC7 may output the 1st DQ data dDQ1 as the 4th data d4 and the 5th data d5. The 8th switching circuit SC8 may output the parity data dPRT. The 11th and 12th switching circuits SC11 and SC12 may output the 0th DQ data dDQ0 as the 10th data d10 and the 11th data d11. The 15th and 16th switching circuits SC15 and SC16 may output the 2nd DQ data dDQ2 as the 14th data d14 and the 15th data d15. Accordingly, the 1st DQ data dDQ1 may be stored in the 2nd sub-memory cell array SMA2.

Referring to FIG. 7B, in a read operation, the switching circuits SC0 to SC7 and SC9 to SC16 may receive the 0th to 15th data d0 to d15 from a corresponding sub-memory cell array (e.g., SMA0 to SMA7), and may receive the DLR data dDLR from the DLR region R_DLR. In addition, the 8th switching circuit SC8 may receive parity data dPRT and DLR data dDLR from the auxiliary sub-memory cell array AMA. The 4th and 5th switching circuits SC4, SC5 may receive the 6th and 7th data d6, d7, respectively, from the 3rd sub-memory cell array SMA3. The 6th and 7th switching circuits SC6, SC7 may receive 4th and 5th data d4, d5, respectively, from the 2nd sub-memory cell array SMA2. The 9th and 10th switching circuits SC9, SC10 may receive the 10th and 11th data d10, d11, respectively, from the 5th sub-memory cell array SMA5. The 11th and 12th switching circuits SC11, SC12 may receive the 8th and 9th data d8, d9, respectively, from the 4th sub-memory cell array SMA4.

Each of the switching circuits SC0 to SC16 may select and output one of a plurality of received data in response to the corresponding gating control signal GA. That is, during a read operation, each of the switching circuits SC0 to SC16 may operate as a multiplexer.

For example, as shown in FIG. 5A, bit lines of the 0th region R0 of the 1st sub-memory cell array SMA1 may be replaced with redundancy bit lines. In this case, the 0th, 1st, 3rd, and 9th to 15th switching circuits SC0, SC1, SC3, and SC9 to SC15 may select and output the 0th, 1st, 3rd, and 8th to 14th data d0, d1, d3, and d8 to d14, respectively, and the 8th switching circuit SC8 may select and output parity data dPRT. The 4th and 5th switching circuits SC4 and SC5 may select and output 6th and 7th data d6 and d7 received from the 3rd sub-memory cell array SMA3. The 6th and 7th switching circuits SC6 and SC7 may select and output 4th and 5th data d4 and d5 received from the 2nd sub-memory cell array SMA2.

In such cases, for example, in the read operation in the first mode, the input/output circuit 190 may output the 10th and 11th data d10 and d11 that have been error-corrected (e.g., by the ECC circuit 180) as the 0th DQ data dDQ0 through the 0th input/output pin P0, output the 4th and 5th data d4 and d5 that have been error-corrected as the 1st DQ data dDQ1 through the 1st input/output pin P1, output the 14th and 15th data d14 and d15 that have been error-corrected as the 2nd DQ data dDQ2 through the 2nd input/output pin, and output the error-corrected DLR data dDLR and the 3rd data d3 as the 3rd DQ data dDQ3 through the 3rd input/output pin.

Further, for example, in the read operation in the second mode, the input/output circuit 190 may output the error-corrected 0th and 1st data d0 and d1 as the 0th DQB data dDQ0B through the 0th input/output pin P0, output the error- corrected 8th and 9th data d8 and d9 as the 1st DQB data DDQ1B through the 1st input/output pin P1, output the error- corrected 6th and 7th data d6 and d7 as the 2nd DQB data dDQ2B through the 2nd input/output pin P2, and output the error- corrected 12th and 13th data d12 and d13 as the 3rd DQB data dDQ3B through the 3rd input/output pin p3.

As already described above, according to some implementations of the present disclosure, when there is a bit line replaced with redundancy bit lines, the memory device 100 may change a storage location of data to be stored in memory cells connected with normal bit lines. In addition, the memory device 100 may adjust an input/output pin to which data read from memory cells is output. Accordingly, even when a failure occurs in the sub-word line driver (e.g., the 4th sub-word line drivers SWD4 or the 5th sub-word line Drivers SWD5) driving the auxiliary sub-memory cell array AMA, the memory device 100 may satisfy the bounded failure condition.

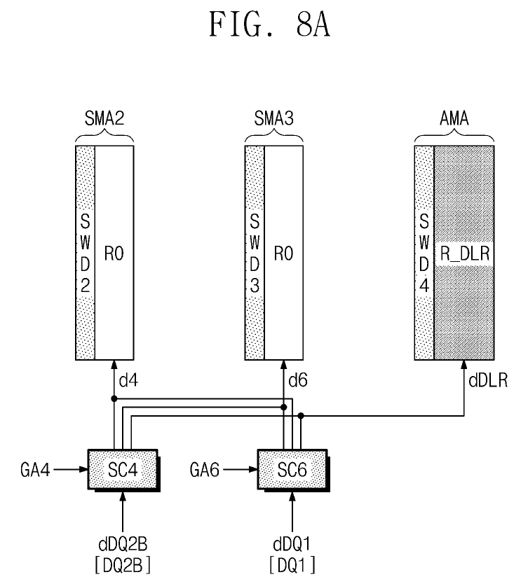

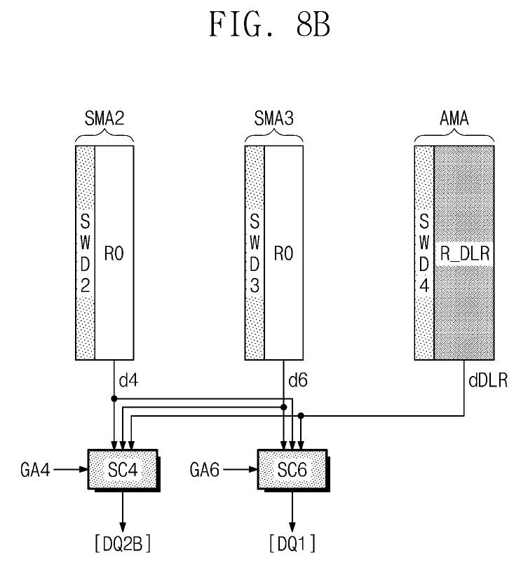

FIGS. 8A and 8B are diagrams for illustrating the operation of the switching circuit of FIGS. 7A and 7B. FIG. 8A is a diagram for describing an operation of a switching circuit during a write operation, and FIG. 8B is a diagram for explaining an operation of a switch circuit during a read operation. For convenience of description, detailed descriptions of unnecessary components and redundant components are omitted.

Referring to FIG. 8A, the 4th switching circuit SC4 may be selectively connected to the 0th region R0 of the 2nd and 3rd sub-memory cell arrays SMA2 and SMA3, and the DLR region R_DLR of the auxiliary sub-memory cell array AMA. For example, in the read operation in the second mode, the 4th switching circuit SC4 may receive the upper 8 bits of the 2nd DQB data dDQ2B received through the 2nd input/output pin P2 operating as the 2nd DQB pin DQ2B. In this case, the 4th switching circuit SC4 may transmit the upper 8 bits of the 2nd DQB data dDQ2B to the 2nd sub-memory cell array SMA2, the 3rd sub-memory cell array SMA3, or the auxiliary sub-memory cell array AMA in response to the 4th gating control signal GA4.

For example, the bit lines of the 0th sub-memory cell array SMA0, the 0th region R0 of the 2nd sub-memory cell array SMA2, the 4th sub-memory cell array SMA4, and the 6th sub-memory cell array SMA6 may be normal bit lines. In this case, the 4th switching circuit SC4 may output the upper 8 bits of the 2nd DQB data dDQ2B as the 4th data d4 in response to the 4th gating control signal GA4. Accordingly, the upper 8 bits of the 2nd DQB data dDQ2B may be stored in the 2nd sub-memory cell array SMA2.

For example, the bit lines of the 0th sub-memory cell array SMA0, the 4th sub-memory cell array SMA4, and the 6th sub-memory cell array SMA6 may be normal bit lines. In addition, bit lines of the 0th region R0 of the 2nd sub-memory cell array SMA2 may be replaced with redundancy bit lines of the DLR region R_DLR. In this case, the 4th switching circuit SC4 may output the upper 8 bits of the 2nd DQB data dDQ2B as the DLR data dDLR in response to the 4th gating control signal GA4. Accordingly, the upper 8 bits of the 2nd DQB data dDQ2B may be stored in the DLR region R_DLR of the auxiliary sub-memory cell array AMA.

For example, some of the bit lines of the 0th sub-memory cell array SMA0, the 4th sub-memory cell array SMA4, and the 6th sub-memory cell array SMA6 may be replaced with redundancy bit lines. In addition, bit lines of the 0th region R0 of the 2nd sub-memory cell array SMA2 may be normal bit lines. In such cases, the 4th switching circuit SC4 may output the upper 8 bits of the 2nd DQB data dDQ2B as the 6th data d6 in response to the 4th gating control signal GA4. Accordingly, the upper 8 bits of the 2nd DQB data dDQ2B may be stored in the 3rd sub-memory cell array SMA3.

For example, in the read operation in the first mode, the 6th switching circuit SC6 may receive the upper 8 bits of the 1st DQ data dDQ1 received through the 1st input/output pin P1 operating as the 1st DQ pin DQ1. In this case, the 6th switching circuit SC6 may transmit the upper 8 bits of the 2nd DQB data dDQ2B to the 2nd sub-memory cell array SMA2, the 3rd sub-memory cell array SMA3, or the auxiliary sub-memory cell array AMA in response to the 6th gating control signal GA6.

For example, the bit lines of the 1st sub-memory cell array SMA1, the 0th region R0 of the 3rd sub-memory cell array SMA3, the 5th sub-memory cell array SMA5, and the 7th sub-memory cell array SMA7 may be normal bit lines. In this case, the 6th switching circuit SC6 may output the upper 8 bits of the 1st DQ data dDQ1 as the 6th data d6 in response to the 6th gating control signal GA6. Accordingly, the upper 8 bits of the 1st DQ data dDQ1 may be stored in the 3rd sub-memory cell array SMA3.

For example, bit lines of the 1st sub-memory cell array SMA1, the 5th sub-memory cell array SMA5, and the 7th sub-memory cell array SMA7 may be normal bit lines. In addition, bit lines of the 0th region R0 of the 3rd sub-memory cell array SMA3 may be replaced with redundancy bit lines of the DLR region R_DLR. In this case, the 6th switching circuit SC6 may output the upper 8 bits of the 1st DQ data dDQ1 as the DLR data dDLR in response to the 6th gating control signal GA6. Accordingly, the upper 8 bits of the 1st DQ data dDQ1 may be stored in the DLR region R_DLR of the auxiliary sub-memory cell array AMA.

For example, some of the bit lines of the 1st sub-memory cell array SMA1, the 5th sub-memory cell array SMA5, and the 7th sub-memory cell array SMA7 may be replaced with redundancy bit lines. In addition, bit lines of the 0th region R0 of the 3rd sub-memory cell array SMA3 may be normal bit lines. In this case, the 6th switching circuit SC6 may output the upper 8 bits of the 1st DQ data dDQ1 as the 4th data d4 in response to the 6th gating control signal GA6. Accordingly, the upper 8 bits of the 1st DQ data dDQ1 may be stored in the 2nd sub-memory cell array SMA2.

Referring to FIG. 8B, in a read operation, the 4th switching circuit SC4 may receive the 4th data d4 from the 2nd sub-memory cell array SMA2, may receive the 6th data d6 from the 3rd sub-memory cell array SMA3, and may receive the DLR data dDLR from the DLR region R_DLR of the auxiliary sub-memory cell array AMA. The 4th switching circuit SC4 may output 4th data d4, 6th data d6, or DLR data dDLR in response to the 4th gating control signal GA4.

For example, the bit lines of the 0th sub-memory cell array SMA0, the 0th region R0 of the 2nd sub-memory cell array SMA2, the 4th sub-memory cell array SMA4, and the 6th sub-memory cell array SMA6 may be normal bit lines. In this case, the 4th switching circuit SC4 may output the 4th data d4 in response to the 4th gating control signal GA4. The 4th data d4 may be output through the 2nd input/output pin P2 that operates as the 2nd DQB pin DQ2B in a read operation in the second mode.

For example, the bit lines of the 0th sub-memory cell array SMA0, the 4th sub-memory cell array SMA4, and the 6th sub-memory cell array SMA6 may be normal bit lines. In addition, bit lines of the 0th region R0 of the 2nd sub-memory cell array SMA2 may be replaced with redundancy bit lines of the DLR region R_DLR. In this case, the 4th switching circuit SC4 may output the DLR data dDLR in response to the 4th gating control signal GA4. The DLR data dDLR may be output through the 2nd input/output pin P2 that operates as the 2nd DQB pin DQ2B in a read operation in the second mode.

For example, some of the bit lines of the 0th sub-memory cell array SMA0, the 4th sub-memory cell array SMA4, and the 6th sub-memory cell array SMA6 may be replaced with redundancy bit lines. Bit lines of the 0th region R0 of the 2nd sub-memory cell array SMA2 may be normal bit lines. In this case, the 4th switching circuit SC4 may output the 6th data d6 in response to the 4th gating control signal GA4. The 6th data d6 may be output through the 2nd input/output pin P2 that operates as the 2nd DQB pin DQ2B in a read operation in the second mode.

In a read operation, the 6th switching circuit SC6 may receive the 4th data d4 from the 2nd sub-memory cell array SMA2, may receive the 6th data d6 from the 3rd sub-memory cell array SMA3, and may receive the DLR data dDLR from the DLR region R_DLR of the auxiliary sub-memory cell array AMA. The 6th switching circuit SC6 may output the 4th data d4, the 6th data d6, or the DLR data dDLR in response to the 6th gating control signal GA6.

For example, the bit lines of the 1st sub-memory cell array SMA1, the 0th region R0 of the 3rd sub-memory cell array SMA3, the 5th sub-memory cell array SMA5, and the 7th sub-memory cell array SMA7 may be normal bit lines. In this case, the 6th switching circuit SC6 may output the 6th data d6 in response to the 6th gating control signal GA6. The 6th data d6 may be output through the 1st input/output pin P1 that operates as the 1st DQ pin DQ1 in a read operation in the first mode.

For example, bit lines of the 1st sub-memory cell array SMA1, the 5th sub-memory cell array SMA5, and the 7th sub-memory cell array SMA7 may be normal bit lines. In addition, bit lines of the 0th region R0 of the 3rd sub-memory cell array SMA3 may be replaced with redundancy bit lines of the DLR region R_DLR. In this case, the 6th switching circuit SC6 may output the DLR data dDLR in response to the 6th gating control signal GA6. The DLR data dDLR may be output through the 1st input/output pin P1 that operates as the 1st DQ pin DQ1 in a read operation in the first mode.

For example, some of the bit lines of the 1st sub-memory cell array SMA1, the 5th sub-memory cell array SMA5, and the 7th sub-memory cell array SMA7 may be replaced with redundancy bit lines. In addition, bit lines of the 0th region R0 of the 3rd sub-memory cell array SMA3 may be normal bit lines. In this case, the 6th switching circuit SC6 may output the 4th data d4 in response to the 6th gating control signal GA6. The 4th data d4 may be output through the 1st input/output pin P1 that operates as the 1st DQ pin DQ1 in a read operation in the first mode.

In some implementations, the 5th and 7th switching circuits SC5, SC7 and the 9th to 12th switching circuits SC9 to SC12 of FIGS. 7A and 7B may operate in a similar manner as the 4th switching circuit SC4 and the 6th switching circuit SC6 of FIGS. 8A and 8B.

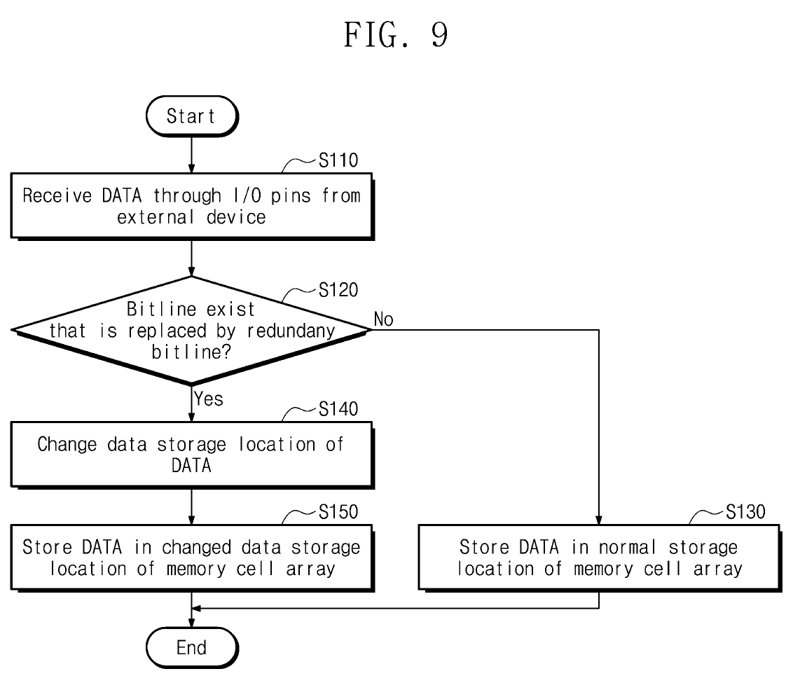

FIG. 9 is a flowchart for illustrating a write operation of the memory device of FIG. 1. Referring to FIG. 9, in step S110, the memory device 100 may receive input/output data DATA. When the memory device 100 operates in the first mode, the input/output data DATA may include 0th to 3rd DQ data dDQ0 to dDQ3 received through the 0th to 3rd input/output pins P0 to P3. When the memory device 100 operates in the second mode, the input/output data DATA may include 0th to 3rd DQB data dDQ0B to dDQ3B received through the 0th to 3rd input/output pins P0 to P3.

In step S120, the memory device 100 may determine whether there is a bit line replaced with a redundancy bit line among bit lines of the sub-memory cell arrays SMA0 to SMA7. When there is no bit line replaced with a redundancy bit line, the memory device 100 may perform step S130. If there is a bit line replaced with a redundancy bit line, the memory device may perform step S140.

In step S130, the memory device 100 may store the input/output data DATA in a general data storage location. Specifically, based on the operation mode, the memory device 100 may store the input/output data DATA in a sub-memory cell array corresponding to the input/output pins P0 to P3 at which the input/output information DATA is received.

For example, the memory device 100 may operate in a first mode. In this case, the memory device 100 may store the 0th DQ data dDQ0 in the 5th sub-memory cell array SMA5, store the 1st DQ data dDQ1 in the 3rd sub-memory cell array SMA3, store the 2nd DQ data dDQ2 in the 7th sub-memory cell array SMA7, and store the 3rd DQ data dSQ3 in the 1st sub-memory cell array SMA1. For example, the memory device 100 may operate in a second mode. In such cases, the memory device 100 may store the 0th DQB data dDQ0B in the 0th sub-memory cell array SMA0, store the 1st DQB data DDQ1B in the 4th sub-memory cell array SMA4, store the 2nd DQB data dDQ2B in the 2nd sub-memory cell array SMA2, and store the 3rd DQB data dDQ3B in the 6th sub-memory cell array SMA6.

For example, the normal storage location may refer to an address area of the sub-memory cell array corresponding to the input/output pins P0 to P3 when the bit lines of the sub-memory cell arrays SMA0 to SMA7 are normal bit lines.

In step S140, the memory device 100 may change the data storage position of the input/output data DATA. Specifically, the memory device 100 may change the storage location of the input/output data DATA based on the location of the sub-memory cell array including the bit line replaced with the redundancy bit line.

For example, some of the bit lines of the 1st sub-memory cell array SMA1, the 5th sub-memory cell array SMA5, or the 7th sub-memory cell array SMA7 may be replaced with redundancy bit lines. In this case, the memory device 100 may change the storage location of the data received through the input/output pin corresponding to the sub-memory cell array including the changed bit lines to the DLR region R_DLR, change the storage position of the 2nd DQB data dDQ2B to the 3rd sub-memory cell array SMA3, and change the storage location the 1st DQ data dDQ1 to the 2nd sub-memory cell array SMA2.

For example, some of the bit lines of the 0th sub-memory cell array SMA0, the 2nd sub-memory cell array SMA2, or the 4th sub-memory cell array SMA4 may be replaced with redundancy bit lines. In this case, the memory device 100 may change the storage location of the data received through the input/output pin corresponding to the sub-memory cell array including the changed bit lines to the DLR region R_DLR, change the storage position of the 1st DQB data dDQ1B to the 5th sub-memory cell array SMA5, and change the storage location for the 0th DQ data dDQ0 to the 4th sub-memory cell array SMA4.

In step S150, the memory device 100 may store the input/output data in the changed data storage location.

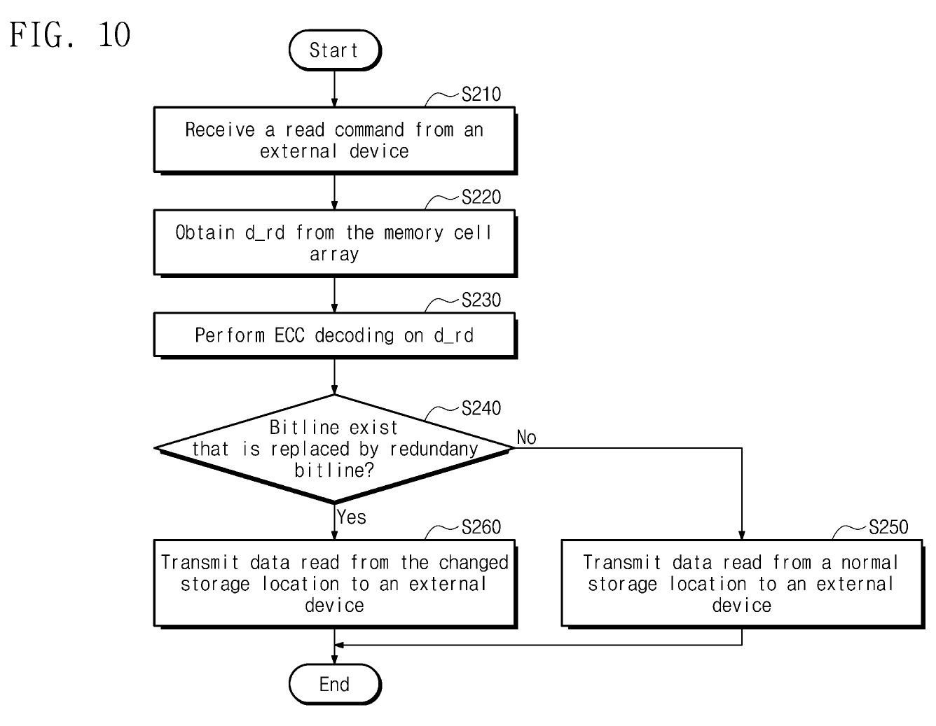

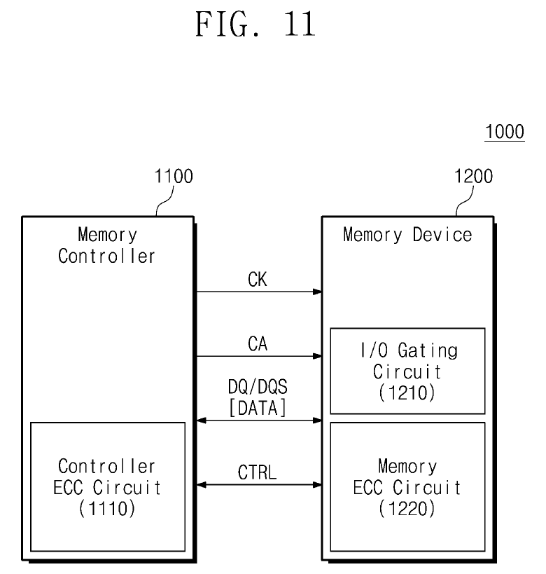

FIG. 10 is a flowchart for illustrating a read operation of the memory device of FIG. 1. Referring to FIG. 10, in step S210, the memory device 100 may receive a read command from an external device (e.g., a memory controller).

In step S220, the memory device 100 may obtain the read data d_rd from the memory cell array 110. For example, data stored in a memory cell array coupled with selected bit lines and selected word lines of the memory cell array 110 may be read.

In step S230, the memory device 100 may perform ECC decoding on the read data d_rd. Accordingly, the memory device 100 may obtain the corrected read data d_rd.

In step S240, the memory device 100 may determine whether there is a bit line replaced with a redundancy bit line among bit lines of the sub-memory cell arrays SMA0 to SMA7. When there is no bit line replaced with a redundancy bit line, the memory device 100 may perform step S250. If there is a bit line replaced with a redundancy bit line, the memory device may perform step S260.

In step S250, the memory device 100 may transmit the corrected data generated based on the read data at the general data storage location of the memory cell array 110 to an external device (e.g., a storage controller) as input/output data DATA.

For example, the memory device 100 may operate in a first mode. In such cases, the memory device 100 may transmit data (e.g., d10, d11) read from the 5th sub-memory cell array SMA5 to the external device through the 0th input/output pin P0, may transmit data (e.g., d2, d3) read from the 3rd sub-memory cell array SMA3 to the external device via the 1st input/output pinP1, may transmit data (e.g., d14, d15) read from the 7th sub-memory cell array SMA7 to the external device though the 2nd input/output pin, and may transmit data (e.g., d2, d3) read from the 1st sub-memory cell array SMA1 to the external device over the 3rd input/output pin.

For example, the memory device 100 may operate in a second mode. In such cases, the memory device 100 may transmit data (e.g., d0, d1) read from the 0th sub-memory cell array SMA0 to an external device through the 0th input/output pin P0, transmit data (e.g., d8, d9) read from the 4th sub-memory cell array SMA4 to the external device through the 1st input/output pinP1, transmit data (e.g., d4, d5) read from the 2nd sub-memory cell array SMA2 to the external device via the 2nd input/output pin, and transmit data (e.g., d12, d13) read from the 6th sub-memory cell array SMA6 to an external device via the 3rd input/output pin P3.

In step S260, the memory device 100 may transmit data read from the changed storage location of the memory cell array 110 as input/output data DATA to an external device (e.g., a storage controller).

For example, some of the bit lines of the 1st sub-memory cell array SMA1, the 5th sub-memory cell array SMA5, or the 7th sub-memory cell array SMA7 may be replaced with redundancy bit lines. In this case, in the read operation in the first mode, the memory device 100 may transmit data read from the DLR region R_DLR to an external device through an input/output pin corresponding to a sub-memory cell array including modified bit lines. In addition, in the read operation in the first mode, the memory device 100 may transmit data (e.g., d4 and d5) read from the 2nd sub-memory cell array SMA2 to an external device through the 1st input/output pin P1. In addition, in the read operation in the second mode, the memory device 100 may transmit data d0, d1, d8, d9, d12, and d13 read from the 0th, 4th, and 6th sub-memory cell arrays SMA0, SMA4, and SMA6 through the 0th, 1st, and 3rd input/output pins P0, P1, and P3, respectively, and transmit data (e.g., d4 and d5) read from the 3rd sub-memory cell array SMA3 through the 2nd input/output pin P2.

For example, some of the bit lines of the 0th sub-memory cell array SMA0, the 2nd sub-memory cell array SMA2, or the 4th sub-memory cell array SMA4 may be replaced with redundancy bit lines. In this case, in the read operation in the first mode, the memory device 100 may transmit data (e.g., d8 and d9) read from the 4th sub-memory cell array SMA4 through the 0th input/output pin P0, and may transmit data (e.g., d6, d7, d14, d15, d2, and d3) read from the 3rd, 7th, and 1st sub-memory cell arrays SMA3, SMA7, and SMA1 through the 1st to 3rd input/output pins P1 to P3, respectively. In addition, the memory device 100 may transmit data read from the DLR region R_DLR to an external device through an input/output pin corresponding to a sub-memory cell array including modified bit lines. In addition, in the read operation in the second mode, the memory device 100 may transmit data (e.g., d10 and d11) read from the 5th sub-memory cell array SMA5 to an external device through the 1st input/output pin P1.

In some implementations, in step S260, data transmitted to the external device through the input/output pins P0 to P3 may be data corrected through ECC decoding in step S230.

FIG. 11 is a diagram for illustrating a memory system according to some implementations of the present disclosure. Referring to FIG. 11, a memory system 1000 may include a memory controller 1100 and a memory device 1200. In some implementations, the memory system 1000 may be one of information processing devices configured to process various information and store the processed information, such as a personal computer, a laptop, a server, a workstation, a smartphone, a tablet PC, a digital camera, a black box, or the like. Alternatively, the memory system 1000 may be a storage medium such as a solid-state drive (SSD), and the memory device 1200 may be used as a buffer memory of the SSD. Alternatively, the memory system 1000 may be included in a graphics processing apparatus configured to perform various graphics processing or operations. However, the scope of the present disclosure is not limited thereto, and the memory system 1000 may be implemented in various forms.

The memory controller 1100 may store data in the memory device 1200 or read data stored in the memory device 1200. For example, the memory controller 1100 may transmit the clock signal CK and the command/address signal CA to the memory device 1200 and may exchange the data signal DQ and the data strobe signal DQS with the memory device 1200. The memory controller 1100 may exchange various control signals CTRL with the memory device 1200. In some implementations, data DATA may be transmitted from the memory controller 1100 to the memory device 1200 or transmitted from the memory device 1200 to the memory controller 110 through the data signal DQ and the data strobe signal DQS. In some implementations, the memory controller 1100 may be a System-on-Chip (SoC) such as an Application Processor (AP).

The memory device 1200 may operate under the control of the memory controller 1100. In some implementations, the memory device 1200 may be a dynamic random-access memory (DRAM) device, but the scope of the present disclosure is not limited thereto, and the memory device 1200 may include a volatile memory such as an SRAM or the like, or a non-volatile memory such as a flash memory, a PRAM, an MRAM, and/or an RRAM.

In some implementations, the memory controller 1100 and the memory device 1200 may communicate with each other based on a predetermined interface. The predetermined interface may be a high-speed interface such as a double data rate (DDR) interface, a low power DDR (LPDDR) interface or a graphics DDR (GDDR), but the scope of the present disclosure is not limited thereto, and may include at least one of various interfaces such as a Universal Serial Bus (USB), a multimedia card (MMC), a peripheral component interconnection (PCI), a PCI-express (PCI-E), an Advanced Technology Attachment (ATA), a Serial-ATA (SATA), a Parallel-ATA (PATA), a small computer small interface (SCSI), an enhanced small disk interface (ESDI), an Integrated Drive Electronics (IDE), a Mobile Industry Processor Interface (MIPI), or a Nonvolatile Memory-express (NVM-e).

In some implementations, the memory controller 1100 may include a controller ECC circuit 1110. In some implementations, the controller ECC circuit 1110 may be configured to correct errors in data received from the memory device 1200.

The memory device 1200 may include an input/output gating circuit 1210 and a memory ECC circuit 1220. The memory device 1200 may correspond to the memory device 100 of FIG. 1, the input/output gating circuit 1210 may correspond to the input/output gate circuit 160 of FIG. 1, and the memory ECC circuit 1220 may correspond to the ECC circuit 180 of FIG. 1. Thus, the memory device 1200 may operate in the manner described with reference to FIGS. 1, 2A, 2B, 3A, 3B, 3C, 4A, 4B, 4C, 4D, 5A, 5B, 5C, 6A, 6B, 6C, 7A, 7B, 8A, 8B, 9, and 10. Accordingly, the memory device 1200 may satisfy the bounded fault condition even if a sub-word line driver fault that drives the auxiliary sub-memory cell array occurs after the faulty bit lines of the sub-memory cell array are replaced with redundancy bit lines.

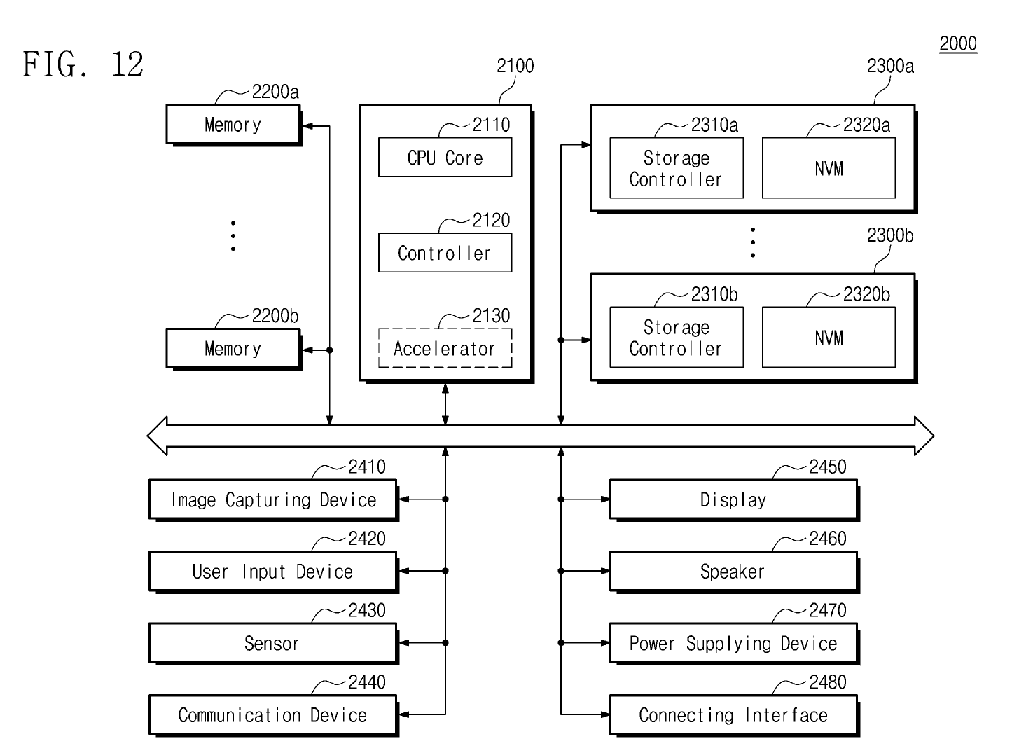

FIG. 12 is a diagram of a system 2000 to which a storage device is applied, according to some implementations. The system 2000 of FIG. 12 may basically be a mobile system, such as a portable communication terminal (e.g., a mobile phone), a smartphone, a tablet personal computer (PC), a wearable device, a healthcare device, or an Internet of things (IOT) device. However, the system 2000 of FIG. 12 is not necessarily limited to the mobile system and may be a PC, a laptop computer, a server, a media player, or an automotive device (e.g., a navigation device).

Referring to FIG. 12, the system 2000 may include a main processor 2100, memories (e.g., 2200a and 2200b), and storage devices (e.g., 2300a and 2300b). In addition, the system 2000 may include at least one of an image capturing device 2410, a user input device 2420, a sensor 2430, a communication device 2440, a display 2450, a speaker 2460, a power supplying device 2470, and a connecting interface 2480.

The main processor 2100 may control all operations of the system 2000, more specifically, operations of other components included in the system 2000. The main processor 2100 may be implemented as a general-purpose processor, a dedicated processor, or an application processor.

The main processor 2100 may include at least one CPU core 2110 and further include a controller 2220 configured to control the memories 2200a and 2200b and/or the storage devices 2300a and 2300b. In some implementations, the main processor 2100 may further include an accelerator 2130, which is a dedicated circuit for a high-speed data operation, such as an artificial intelligence (AI) data operation. The accelerator 2130 may include a graphics processing unit (GPU), a neural processing unit (NPU) and/or a data processing unit (DPU) and be implemented as a chip that is physically separate from the other components of the main processor 2100.

The memories 2200a and 2200b may be used as main memory devices of the system 2000. Although each of the memories 2200a and 2200b may include a volatile memory, such as static random access memory (SRAM) and/or dynamic RAM (DRAM), each of the memories 2200a and 2200b may include non-volatile memory, such as a flash memory, phase-change RAM (PRAM) and/or resistive RAM (RRAM). The memories 2200a and 2200b may be implemented in the same package as the main processor 2100.

The storage devices 2300a and 2300b may serve as non-volatile storage devices configured to store data regardless of whether power is supplied thereto and have larger storage capacity than the memories 2200a and 2200b. The storage devices 2300a and 2300b may respectively include storage controllers (STRG CTRL) 2310a and 2310b and NVMs (Non-Volatile Memories) 2320a and 2320b configured to store data via the control of the storage controllers 2310a and 2310b. Although the NVMs 2320a and 2320b may include flash memories having a two-dimensional (2D) structure or a three-dimensional (3D) V-NAND structure, the NVMs 2320a and 2320b may include other types of NVMs, such as PRAM and/or RRAM.

The storage devices 2300a and 2300b may be physically separated from the main processor 2100 and included in the system 2000 or implemented in the same package as the main processor 2100. In addition, the storage devices 2300a and 2300b may have types of solid-state devices (SSDs) or memory cards and be removably combined with other components of the system 100 through an interface, such as the connecting interface 2480 that will be described below. The storage devices 2300a and 2300b may be devices to which a standard protocol, such as a universal flash storage (UFS), an embedded multi-media card (eMMC), or a non-volatile memory express (NVMe), is applied, without being limited thereto.

The image capturing device 2410 may capture still images or moving images. The image capturing device 2410 may include a camera, a camcorder, and/or a webcam.

The user input device 2420 may receive various types of data input by a user of the system 2000 and include a touch pad, a keypad, a keyboard, a mouse, and/or a microphone.

The sensor 2430 may detect various types of physical quantities, which may be obtained from the outside of the system 2000 and convert the detected physical quantities into electric signals. The sensor 2430 may include a temperature sensor, a pressure sensor, an illuminance sensor, a position sensor, an acceleration sensor, a biosensor, and/or a gyroscope sensor.

The communication device 2440 may transmit and receive signals between other devices outside the system 2000 according to various communication protocols. The communication device 2440 may include an antenna, a transceiver, and/or a modem.

The display 2450 and the speaker 2460 may serve as output devices configured to respectively output visual information and auditory information to the user of the system 2000.

The power supplying device 2470 may appropriately convert power supplied from a battery (not shown) embedded in the system 2000 and/or an external power source and supply the converted power to each of components of the system 2000.

The connecting interface 2480 may provide connection between the system 2000 and an external device, which is connected to the system 2000 and capable of transmitting and receiving data to and from the system 2000. The connecting interface 2480 may be implemented by using various interface schemes, such as advanced technology attachment (ATA), serial ATA (SATA), external SATA (e-SATA), small computer system interface (SCSI), serial attached SCSI (SAS), peripheral component interconnection (PCI), PCI express (PCIe), NVMe, IEEE 1394, a universal serial bus (USB) interface, a secure digital (SD) card interface, a multi-media card (MMC) interface, an eMMC interface, a UFS interface, an embedded UFS (eUFS) interface, and a compact flash (CF) card interface.

In some implementations, the memories 2200a and 2200b may be the memory device described with reference to FIGS. 1, 2A, 2B, 3A, 3B, 3C, 4A, 4B, 4C, 4D, 5A, 5B, 5C, 6A, 6B, 6C, 7A, 7B, 8A, 8B, 9, and 10. The memories 2200a and 2200b may operate based on the operation method described with reference to FIGS. 1, 2A, 2B, 3A, 3B, 3C, 4A, 4B, 4C, 4D, 5A, 5B, 5C, 6A, 6B, 6C, 7A, 7B, 8A, 8B, 9, and 10.

While this specification contains many specific implementation details, these should not be construed as limitations on the scope of any invention or on the scope of what may be claimed, but rather as descriptions of features that may be specific to particular implementations of particular inventions. Certain features that are described in this specification in the context of separate implementations can also be implemented in combination in a single implementation. Conversely, various features that are described in the context of a single implementation can also be implemented in multiple implementations separately or in any suitable subcombination. Moreover, although features may be described above as acting in certain combinations, one or more features from a combination can in some cases be excised from the combination, and the combination may be directed to a subcombination or variation of a subcombination.

The above description refers to detailed implementations for carrying out the present disclosure. The present disclosure may include implementations in which a design is changed simply or which are easily changed, as well as some implementations described above. In addition, technologies that are easily changed and implemented by using the above implementations may be included in the present disclosure. While the present disclosure has been described with reference to implementations thereof, it will be apparent to those of ordinary skill in the art that various changes and modifications may be made thereto without departing from the spirit and scope of the present disclosure as set forth in the following claims.

What is claimed is:

1. A memory device comprising:
a memory cell array comprising
a first sub-memory cell array corresponding to a first address region and including a plurality of first bit lines,
a second sub-memory cell array corresponding to a second address region and including a plurality of second bit lines,
a third sub-memory cell array corresponding to a third address region and including a plurality of third bit lines, and
a fourth sub-memory cell array corresponding to a fourth address region and including a plurality of redundancy bit lines configured to replace faulty bit lines among the plurality of first bit lines, the plurality of second bit lines, and the plurality of third bit lines; and
a peripheral circuit configured to
receive first data and second data corresponding to the first address region and the second address region, respectively, through a first input/output pin and a second input/output pin from an external device, and
based on at least one of the pluralities of first bit lines having been replaced with at least one of the pluralities of redundancy bit lines, store the first data in the fourth sub-memory cell array and the second data in the third sub-memory cell array.

2. The memory device of claim 1, wherein the second sub-memory cell array is adjacent to the third sub-memory cell array and the fourth sub-memory cell array.

3. The memory device of claim 1, wherein the peripheral circuit is configured to:
store the first data in the first sub-memory cell array and store the second data in the second sub-memory cell array based on the plurality of first bit lines, the plurality of second bit lines and the plurality of third bit lines have not been replaced with the plurality of redundancy bit lines.

4. The memory device of claim 1, wherein the memory cell array comprises:
a fifth sub-memory cell array corresponding to a fifth address region and including a plurality of fifth bit lines;
a sixth sub-memory cell array corresponding to a sixth address region and including a plurality of sixth bit lines;
a seventh sub-memory cell array corresponding to a seventh address region and including a plurality of seventh bit lines;
an eighth sub-memory cell array corresponding to an eighth address region and including a plurality of eighth bit lines, and
a ninth sub-memory cell array corresponding to a ninth address region,
wherein the peripheral circuit comprises an input/output circuit including the first input/output pin, the second input/output pin, a third input/output pin and a fourth input/output pin; and
wherein the first to fourth input/output pins are configured to
receive, during a write operation in a first mode, the first data, the second data, third data corresponding to the fifth address region, and fourth data corresponding to the sixth address region, respectively, from the external device, and
receive, during a write operation in a second mode, fifth data corresponding to the third address region, and sixth data, seventh data, and eighth data corresponding to the seventh address region, the eight address region and the ninth address region, respectively, from the external device.

5. The memory device of claim 4, wherein the peripheral circuit comprises:
control logic circuitry configured to generate a gating control signal associated with a storage location of (i) the first data, the second data, the third data and the fourth data or (ii) the fifth data, the sixth data, the seventh data, and the eighth data; and
an input/output gating circuit configured to transmit (i) the first data, the second data, the third data, and the fourth data or (ii) the fifth data, the sixth data, the seventh data, and the eighth data to the memory cell array based on the gating control signal.

6. The memory device of claim 5, wherein the input/output gating circuit is configured to, during a write operation in the first mode:
based on at least one of the pluralities of first bit lines having been replaced with the plurality of redundancy bit lines, transfer the first data to the fourth sub-memory cell array, transfer the second data to the third sub-memory cell array, transfer the third data to the fifth sub-memory cell array, and transfer the fourth data to the sixth sub-memory cell array; and
based on at least one of the pluralities of first bit lines having not been replaced with the plurality of redundancy bit lines, transfer the first data to the first sub-memory cell array, transfer the second data to the second sub-memory cell array, transfer third data to the fifth sub-memory cell array, and transfer the fourth data to the sixth sub-memory cell array.

7. The memory device of claim 5, wherein the input/output gating circuit is configured to, during a write operation in the second mode:
based on at least one of the pluralities of seventh bit lines having been replaced with the plurality of redundancy bit lines, transfer the fifth data to the fourth sub-memory cell array, transfer the sixth data to the fifth sub-memory cell array, transfer the seventh data to the eighth sub-memory cell array, and transfer the eighth data to the ninth sub-memory cell array; and
based on at least one of the pluralities of seventh bit lines having not been replaced with the plurality of redundancy bit lines, transfer the fifth data to the third sub-memory cell array, transfer the sixth data to the seventh sub-memory cell array, transfer the seventh data to the eighth sub-memory cell array, and transfer the eighth data to the ninth sub-memory cell array.

8. The memory device of claim 6, wherein the input/output gating circuit includes a plurality of switching circuits including a first switching circuit,
wherein the first switching circuit configured to:
receive the second data;
based on the plurality of first bit lines having been replaced with the plurality of redundancy bit lines, transfer the second data to the third sub-memory cell array;
based on the plurality of second bit lines having been replaced with the plurality of redundancy bit lines, transfer the second data to the fourth sub-memory cell array; and
based on the plurality of first bit lines, the plurality of second bit lines, the plurality of third bit lines, a plurality of fourth bit lines, a plurality of fifth bit lines, a plurality of sixth bit lines, a plurality of seventh bit lines, and a plurality of eighth bit lines being normal bit lines, transfer the second data to the second sub-memory cell array.

9. The memory device of claim 1, wherein the peripheral circuit is configured to, in a read operation on the first data and the second data,
perform error correction code (ECC) decoding on the first data read from the fourth sub-memory cell array and the second data read from the third sub-memory cell array to generate corrected first data and corrected second data;
transmit the corrected first data to the external device through the first input/output pin; and
transmit the corrected second data to the external device via the second input/output pin.

10. The memory device of claim 9, wherein the fourth sub-memory cell array includes a first region including the plurality of redundancy bit lines and a second region including memory cells in which parity data for the ECC decoding is stored.

11. The memory device of claim 1, wherein the memory cell array includes a plurality of sub-word line drivers configured to drive word lines of the first sub-memory cell array, the second sub-memory cell array, the third sub-memory cell array, and the fourth sub-memory cell array.

12. A method of operating a memory device comprising:
receiving first data and second data corresponding to a first address region and a second address region, respectively, through a first input/output pin and a second input/output pin, wherein the first address region and the second address region correspond, respectively, to a first sub-memory cell array comprising a plurality of first bit lines and a second sub-memory cell array comprising a plurality of second bit lines;
based on determining that at least one of the pluralities of first bit lines of the first sub-memory cell array has been replaced with a plurality of redundancy bit lines of a fourth sub-memory cell array, storing the first data in the fourth sub-memory cell array and storing the second data in a third sub-memory cell array corresponding to a third address region and comprising a plurality of third bit lines.

13. The method of claim 12, wherein the second sub-memory cell array is adjacent to the third sub-memory cell array and the fourth sub-memory cell array.

14. The method of claim 12, wherein
based on the plurality of first bit lines of the first sub-memory cell array, the plurality of second bit lines of the second sub-memory cell array, and the plurality of third bit lines of the third sub-memory cell array not having been replaced with the plurality of redundancy bit lines,
storing the first data in the first sub-memory cell array; and
storing the second data in the second sub-memory cell array.

15. The method of claim 12, wherein:
receiving, a read command for the first data and the second data;
based on at least one of the pluralities of first bit lines of the first sub-memory cell array having been replaced with the plurality of redundancy bit lines, reading the first data in the fourth sub-memory cell array and the second data in the third sub-memory cell array;\
performing error correction coding decoding on the first data and the second data to generate a corrected first data and a corrected second data; and
outputting the corrected first data through the first input/output pin and outputting the corrected second data through the second input/output pin.

16. A memory system comprising a memory device and a memory controller configured to control the memory device,
wherein the memory device comprises:
a memory cell array comprising a first sub-memory cell array, a second sub-memory cell array, a third sub-memory cell array, a fourth sub-memory cell array, and a fifth sub-memory cell array respectively corresponding to a first address region, a second address region, a third address region, a fourth address region, and a fifth address region and each comprising a plurality of bit lines and a sixth sub-memory cell array corresponding to a sixth address region, wherein the sixth sub-memory cell array comprises a plurality of redundancy bit lines configured to replace faulty bit lines;
an input/output circuit including a first input/output pin, a second input/output pin, a third input/output pin, and a fourth input/output pin, and configured to respectively receive, from the memory controller, first data, second data, third data, and fourth data respectively corresponding to the first address region, the second address region, the third address region, and the fourth address region through the first input/output pin, the second input/output pin, the third input/output pin, and the fourth input/output pin;
an error correction code (ECC) circuit configured to perform error correction code encoding on the first data, the second data, the third data, and the fourth data to generate write data including the first data, the second data, the third data, the fourth data and parity data;
an input/output gating circuit configured to transfer the write data to the memory cell array; and
a control logic circuit configured to generate a gating control signal associated with a storage location of the first data, the second data, the third data, and the fourth data,
wherein the input/output gating circuit is configured to
based on at least one of the pluralities of bit lines of the first sub-memory cell array having been replaced with the plurality of redundancy bit lines,
transfer, based on the gating control signal, the first data to the sixth sub-memory cell array, the second data to the fifth sub-memory cell array, the third data to the third sub-memory cell array, and the fourth data to the fourth sub-memory cell array.

17. The memory system of claim 16, wherein the first data is stored in the sixth sub-memory cell array, the second data is stored in the fifth sub-memory cell array, the third data is stored in the third sub-memory cell array, and the fourth data is stored in the fourth sub-memory cell array.

18. The memory system of claim 16, wherein the second sub-memory cell array is adjacent to the fifth sub-memory cell array and the sixth sub-memory cell array.

19. The memory system of claim 16, wherein the input/output gating circuit is configured to:
based on the plurality of bit lines of the first sub-memory cell array, the second sub-memory cell array, the third sub-memory cell array, and the fourth sub-memory cell array having not been replaced with the plurality of redundancy bit lines,
transfer the first data to the first sub-memory cell array, the second data to the second sub-memory cell array, third data to the third sub-memory cell array, and fourth data to the fourth sub-memory cell array.

20. The memory system of claim 16, wherein the input/output gating circuit includes a plurality of switching circuits,
wherein a first switching circuit of the plurality of switching circuits is configured to:
receive the second data; and
based on the plurality of bit lines of the first sub-memory cell array having been replaced with the plurality of redundancy bit lines, transfer the second data to the fifth sub-memory cell array, and
based on the plurality of bit lines of the second sub-memory cell array having been replaced with the plurality of redundancy bit lines, forward the second data to the sixth sub-memory cell array, and
based on the plurality of bit lines being normal bit lines, transfer the second data to the second sub-memory cell array.
